(19) United States
(12) Patent Application Publication
(10) Pub. No.: US 2025/0386588 A1
(43) Pub. Date: Dec. 18, 2025

(54) SEMICONDUCTOR DEVICE

(71) Applicant: FUJI ELECTRIC CO., LTD., Kanagawa (JP)

(72) Inventor: Takahiro TAMURA, Matsumoto-city (JP)

(21) Appl. No.: 19/218,338

(22) Filed: May 25, 2025

(30) Foreign Application Priority Data
Jun. 14, 2024 (JP) 2024-096766

(51) Int. Cl. H10D 84/00; H10D 8/01; H10D 8/60; H10D 12/00; H10D 62/10; H10D 62/60; H10D 64/23

(52) U.S. Cl. CPC H10D 84/161; H10D 8/051; H10D 8/60; H10D 12/415; H10D 12/481; H10D 62/124; H10D 62/60; H10D 64/232

(57) ABSTRACT

Provided is a semiconductor device which includes a diode portion, the semiconductor device includes: a drift region of a first conductivity type which is provided in a semiconductor substrate; a plurality of trench portions which extend in a predetermined trench extending direction on a front surface side of the semiconductor substrate; and a front-surface electrode portion which is provided above a front surface of the semiconductor substrate, the diode portion includes a plug region of a second conductivity type which is provided in the semiconductor substrate and in contact with the front-surface electrode portion, and a first conductivity type mesa region of the first conductivity type which is in contact with the plug region in a mesa portion between the plurality of trench portions.

The contents of the following patent application(s) are incorporated herein by reference: 2024-096766 filed in JP on Jun. 14, 2024

### BACKGROUND

### 1. Technical Field

The present invention relates to a semiconductor device.

### 2. Related Art

A diode portion including an anode region of a P type is known (see, for example, Patent Documents 1 and 2).
Patent Document 1: International Publication No. 2015/050262
Patent Document 2: Japanese Patent Application Publication No. 2023-172272

### BRIEF DESCRIPTION OF THE DRAWINGS

FIG. 1 illustrates an example of a top view of a semiconductor device 100.

FIG. 2A is an enlarged view of a region A in FIG. 1.

FIG. 2B is a view illustrating an example of an XZ cross section including an a-a′ cross section in FIG. 2A.

FIG. 2C is a view illustrating an example of an XZ cross section including a b-b′ cross section in FIG. 2A.

FIG. 2D is an enlarged view of an XZ cross section passing through a mesa portion 81.

FIG. 2E illustrates an example of a YZ cross section including a c-c′ cross section in FIG. 2A.

FIG. 3A is an enlarged view of a modification of the XZ cross section passing through the mesa portion 81.

FIG. 3B is an enlarged view of a modification of the XZ cross section passing through the mesa portion 81.

FIG. 4A is a top view of a modification of the semiconductor device 100.

FIG. 4B is a view illustrating an example of an XZ cross section including a d-d′ cross section in FIG. 4A.

FIG. 5A is a top view of a modification of the semiconductor device 100.

FIG. 5B is a view illustrating an example of an XZ cross section including an e-e′ cross section in FIG. 5A.

FIG. 6A is a top view of a modification of the semiconductor device 100.

FIG. 6B is a view illustrating an example of an XZ cross section including an f-f′ cross section in FIG. 6A.

FIG. 7A is a top view of a modification of the semiconductor device 100.

FIG. 7B is a view illustrating an example of an XZ cross section including a g-g′ cross section in FIG. 7A.

FIG. 7C is a view illustrating an example of an XZ cross section including an h-h′ cross section in FIG. 7A.

FIG. 8A is a view illustrating a modification of the XZ cross section including the a-a′ cross section in FIG. 2A.

FIG. 8B is a view illustrating a modification of the XZ cross section including the a-a′ cross section in FIG. 2A.

FIG. 8C is a view illustrating a modification of the XZ cross section including the a-a′ cross section in FIG. 2A.

FIG. 9 is an enlarged view of a modification of the XZ cross section passing through the mesa portion 81.

FIG. 10A is an enlarged view of a modification of the XZ cross section passing through the mesa portion 81.

FIG. 10B is a modification of the XZ cross section passing through the mesa portion 81.

FIG. 11A is a top view of a modification of the semiconductor device 100.

FIG. 11B is a view illustrating an example of an XZ cross section including an i-i′ cross section in FIG. 11A.

FIG. 12A is a top view of a modification of the semiconductor device 100.

FIG. 12B is a view illustrating an example of an XZ cross section including a j-j′ cross section in FIG. 12A.

FIG. 13A is a top view of a modification of the semiconductor device 100.

FIG. 13B is a view illustrating an example of an XZ cross section including a k-k′ cross section in FIG. 13A.

FIG. 14 is an example of a cross-sectional view of the semiconductor device 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, a direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, the doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

In the present specification, a description of a P+ type or an N+ type means a higher doping concentration than that of the P type or the N type, and a description of a P− type or an N− type means a lower doping concentration than that of the P type or the N type. In addition, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier means a charge carrier of an electron or a hole. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

In addition, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. A decrease in carrier mobility occurs when carriers are scattered due to disorder of a crystal structure due to a lattice defect or the like. The carrier concentration decreases for a following reason. In the SRP method, the spreading resistance is measured, and the carrier concentration is converted from a measurement value of the spreading resistance. At this time, mobility of the crystalline state is used as the carrier mobility. On the other hand, despite the fact that the carrier mobility has decreased at a position where the lattice defect is introduced, the carrier concentration is calculated by using the carrier mobility of the crystalline state. Therefore, a value lower than an actual carrier concentration, that is, a concentration of the donor or the acceptor, is obtained.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is about 99% of chemical concentrations of these. On the other hand, in the silicon semiconductor, a donor concentration of hydrogen serving as a donor is about 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. As for numeric representation of power of 10, for example, the representation 1E+16 indicates 1×10¹⁶, and the representation 1E-16 indicates 1×10⁻¹⁶.

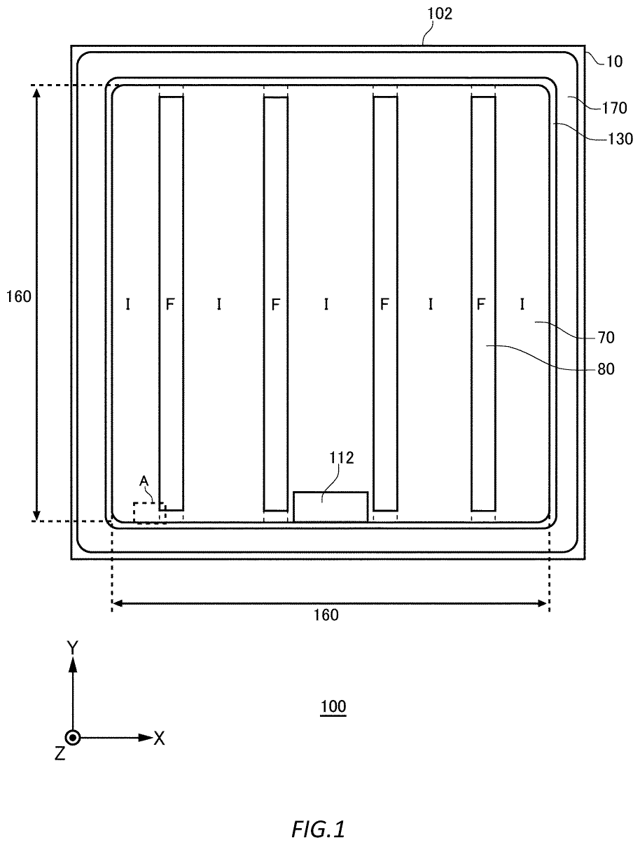

FIG. 1 illustrates an example of a top view of a semiconductor device 100. FIG. 1 illustrates a position at which each member is projected on an upper surface of a semiconductor substrate 10. FIG. 1 illustrates only some members of the semiconductor device 100, and illustration of some members is omitted. The semiconductor device 100 is a semiconductor chip including a transistor portion 70 and a diode portion 80.

The transistor portion 70 includes a transistor such as an insulated gate bipolar transistor (IGBT). The diode portion 80 includes a diode such as a free wheel diode (FWD). The semiconductor device 100 of the present example is a reverse conducting IGBT (RC-IGBT) having the transistor portion 70 and the diode portion 80 on a same chip.

The semiconductor substrate 10 is a substrate that is formed of a semiconductor material. The semiconductor substrate 10 may be a silicon substrate, may be a silicon carbide substrate, may be a diamond substrate, may be a nitride semiconductor substrate such as gallium nitride, may be an inorganic compound semiconductor substrate such as gallium oxide, or may be an organic compound semiconductor substrate. The semiconductor substrate 10 in the present example is the silicon substrate. The semiconductor substrate 10 may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), or a float zone method (FZ method).

The semiconductor substrate 10 has an end side 102 in top view. When merely referred to as the top view in the present specification, it means that the semiconductor substrate 10 is viewed from an upper surface side. The semiconductor substrate 10 in the present example has two sets of end sides 102 facing each other in top view. In FIG. 1, the X axis and the Y axis are parallel to any of the end sides 102. In addition, the Z axis is perpendicular to the upper surface of the semiconductor substrate 10. The semiconductor substrate 10 includes an active region 160 and an edge termination structure portion 170.

The active region 160 is a region where a main current flows in the depth direction between the upper surface and the lower surface of the semiconductor substrate 10 during an operation of the semiconductor device 100. An emitter electrode is provided above the active region 160, but is omitted in FIG. 1.

The active region 160 is provided with at least one of the transistor portion 70 including a transistor element such as an IGBT or the diode portion 80 including a diode element such as a free wheel diode (FWD). In the example of FIG. 1, the transistor portion 70 and the diode portion 80 are alternately arranged along a predetermined array direction (the X axis direction in the present example) on the upper surface of the semiconductor substrate 10.

In FIG. 1, a region where the transistor portion 70 is arranged is indicated by a symbol “I”, and a region where the diode portion 80 is arranged is indicated by a symbol “F”. In the present specification, a direction perpendicular to the array direction in top view may be referred to as an extending direction (the Y axis direction in FIG. 1). The transistor portion 70 and the diode portion 80 may each have a longitudinal length in the extending direction. In other words, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80 may be the same as a longitudinal direction of each trench portion described later.

The diode portion 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps the cathode region in top view. A collector region of the P+ type may be provided in a region other than the cathode region on the lower surface of the semiconductor substrate 10.

The transistor portion 70 includes a collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may include one or more pads above the semiconductor substrate 10. The semiconductor device 100 of the present example includes a gate pad 112. The semiconductor device 100 may include a pad such as an anode pad, a cathode pad, and a current detection pad. Each pad is arranged in a vicinity of the end side 102. The vicinity of the end side 102 refers to a region between the end side 102 and the emitter electrode in top view. When the semiconductor device 100 is mounted, each pad may be connected to an external circuit via a wiring line such as a wire.

A gate potential is applied to the gate pad 112. The gate pad 112 is electrically connected to a conductive portion of a gate trench portion of the active region 160. The semiconductor device 100 includes a gate runner 130 that connects the gate pad 112 and the gate trench portion.

The gate runner 130 is electrically connected to the gate conductive portion of the transistor portion 70 and applies a gate voltage to the transistor portion 70. The gate runner 130 is provided so as to surround an outer periphery of the active region 160 in top view. The gate runner 130 is electrically connected to the gate pad 112 provided in the edge termination structure portion 170.

In addition, the semiconductor device 100 may include a temperature sensing unit (not illustrated) that is a PN junction diode formed of polysilicon or the like, and a current detection unit (not illustrated) that simulates an operation of a transistor portion provided in the active region 160.

The semiconductor device 100 of the present example includes an edge termination structure portion 170 between the active region 160 and the end side 102 in top view. The edge termination structure portion 170 of the present example is arranged between the gate runner 130 and the end side 102. The edge termination structure portion 170 reduces an electric field strength on the upper surface side of the semiconductor substrate 10. The edge termination structure portion 170 may include at least one of a guard ring, a field plate, or a RESURF which is annularly provided to enclose the active region 160.

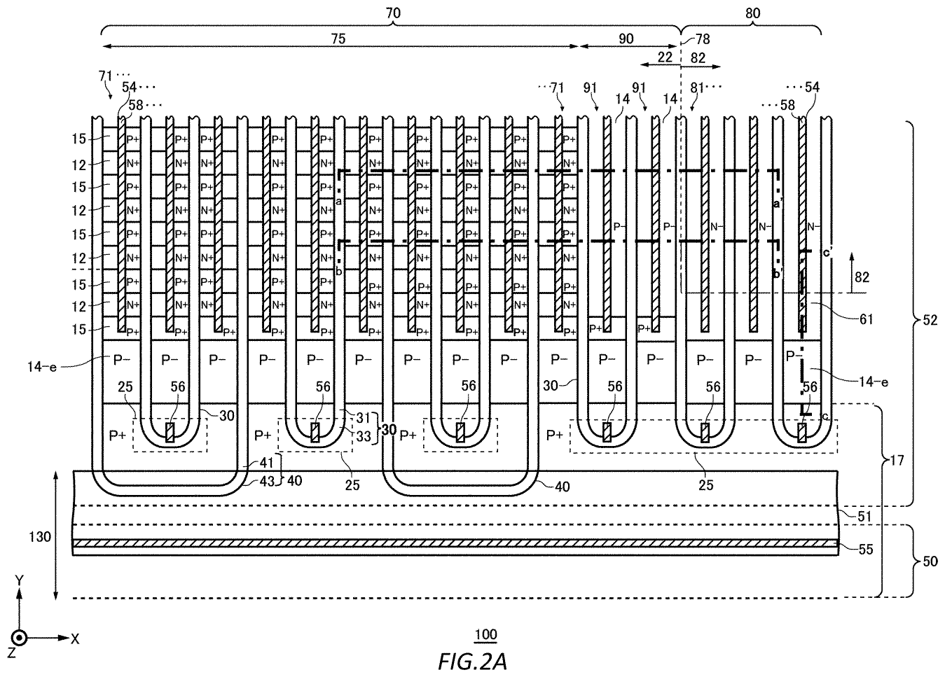

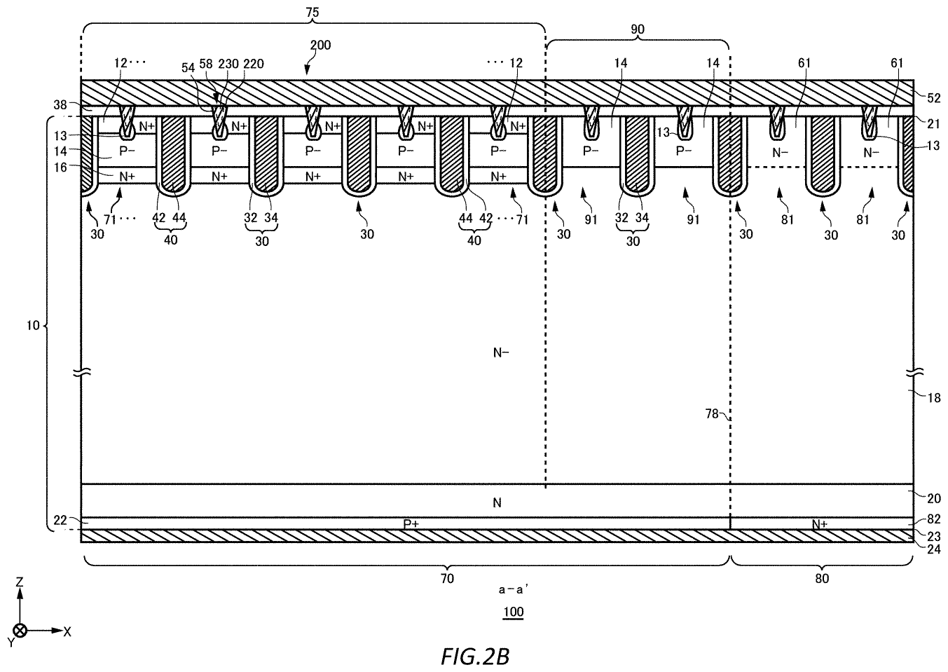

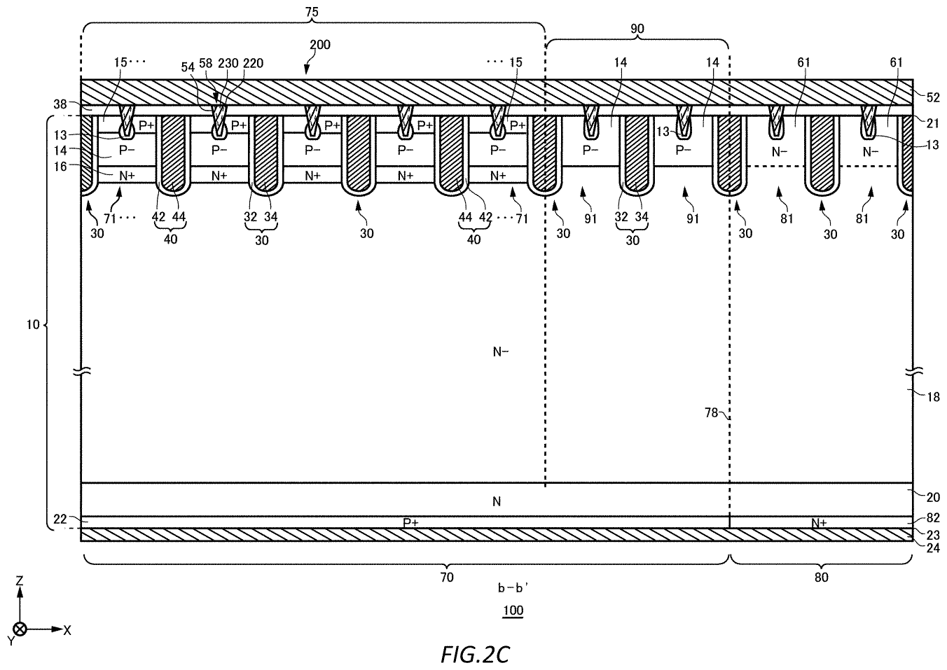

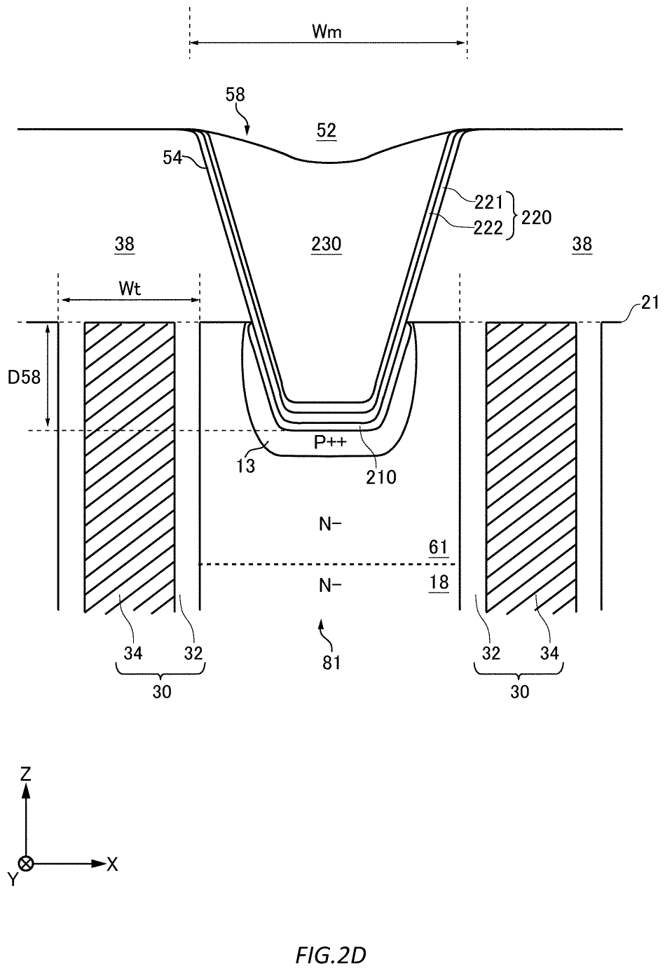

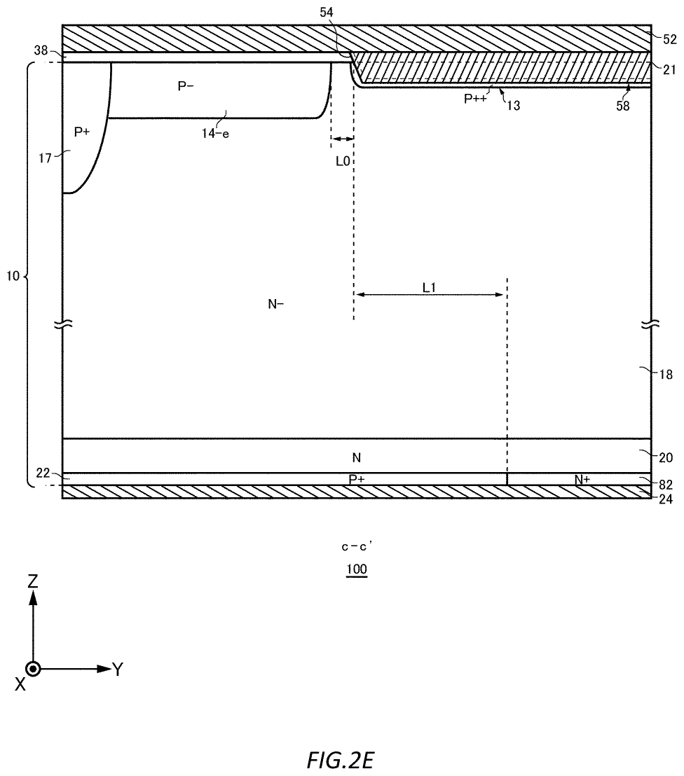

FIG. 2A is an enlarged view of a region A in FIG. 1. The region A is a region including the transistor portion 70, the diode portion 80, and the gate runner 130. The gate runner 130 of the present example includes a gate metal layer 50 and a gate runner portion 51.

The transistor portion 70 includes a main region 75 and a boundary region 90. On a front surface 21 of the semiconductor substrate 10, the boundary region 90 is provided between the main region 75 of the transistor portion 70 and the diode portion 80. The front surface 21 of the semiconductor substrate 10 refers to one of the two principal surfaces facing each other in the semiconductor substrate 10. The front surface 21 will be described later.

The semiconductor device 100 of the present example includes a gate trench portion 40, a dummy trench portion 30, a well region 17, an emitter region 12, a base region 14, and a contact region 15 that are formed inside the front surface 21 side of the semiconductor substrate 10. In addition, the semiconductor device 100 in the present example includes an emitter electrode 52 and a gate metal layer 50 which are provided above the front surface 21 of the semiconductor substrate 10. The emitter electrode 52 and the gate metal layer 50 are provided separated from each other.

An interlayer dielectric film is formed between the emitter electrode 52 and the gate metal layer 50, and the front surface 21 of the semiconductor substrate 10, but the interlayer dielectric film is omitted in FIG. 2A. In the interlayer dielectric film of the present example, a contact hole 54, a contact hole 55, and a contact hole 56 are formed to penetrate the interlayer dielectric film.

The emitter electrode 52 is electrically connected to the emitter region 12, the contact region 15, and the base region 14 on the front surface 21 of the semiconductor substrate 10 through the contact hole 54 formed in the interlayer dielectric film. In addition, the emitter electrode 52 is connected to a dummy conductive portion inside the dummy trench portion 30 through the contact hole 56. Between the emitter electrode 52 and the dummy conductive portion, a connection portion 25 formed of a conductive material such as polysilicon doped with impurities may be provided.

The gate metal layer 50 is in contact with the gate runner portion 51 through the contact hole 55. The gate runner portion 51 is formed of a semiconductor such as polysilicon doped with impurities. The gate runner portion 51 is connected to a gate conductive portion inside the gate trench portion 40 on the front surface 21 of the semiconductor substrate 10.

The emitter electrode 52 and the gate metal layer 50 are formed of a material containing metal. At least a partial region of the emitter electrode 52 may be formed of metal such as aluminum (AI) or of a metal alloy such as an aluminum-silicon alloy (AlSi) or an aluminum-silicon-copper alloy (AlSiCu). At least a partial region of the gate metal layer 50 may be formed of metal such as aluminum (AI) or of a metal alloy such as an aluminum-silicon alloy (AlSi) or an aluminum-silicon-copper alloy (AlSiCu). The emitter electrode 52 and the gate metal layer 50 may have barrier metal formed of titanium, a titanium compound, or the like under a region formed of aluminum or the like. Each electrode may further include a plug, which is formed by embedding tungsten or the like so as to be in contact with the barrier metal and aluminum or the like, in the contact hole.

The well region 17 is provided so as to overlap the gate metal layer 50 and the gate runner portion 51. The well region 17 is provided to extend with a predetermined width also in a range not overlapping the gate metal layer 50 and the gate runner portion 51. The well region 17 of the present example is provided apart from an end of the contact hole 54 in the Y axis direction toward the gate metal layer 50. The well region 17 is a region of a second conductivity type which is provided in the semiconductor substrate 10. A doping concentration of the well region 17 may be higher than a doping concentration of the base region 14. The base region 14 in the present example is the P− type, and the well region 17 is the P+ type.

Each of the transistor portion 70 and the diode portion 80 includes a plurality of trench portions, which are aligned in a trench array direction, on the front surface 21 of the semiconductor substrate 10. In the transistor portion 70 of the present example, one or more gate trench portions 40 and one or more dummy trench portions 30 are alternately provided along the trench array direction. In the diode portion 80 of the present example, a plurality of dummy trench portions 30 is provided along the trench array direction. The diode portion 80 of the present example is not provided with the gate trench portion 40. Note that the trench array direction may be the same as or different from the array direction of the transistor portion 70 and the diode portion 80. The trench array direction of the present example is the same as the array direction of the transistor portion 70 and the diode portion 80.

In the transistor portion 70, one or more gate trench portions 40 are aligned at predetermined intervals along the trench array direction. The gate conductive portion inside the gate trench portion 40 is electrically connected to the gate metal layer 50, and a gate potential is applied thereto. In the transistor portion 70, one or more dummy trench portions 30 may be aligned at predetermined intervals along the trench array direction. A potential different from the gate potential is applied to the dummy conductive portion inside the dummy trench portion 30. The dummy conductive portion of the present example is electrically connected to the emitter electrode 52, and an emitter potential is applied thereto.

In the transistor portion 70, one or more gate trench portions 40 and one or more dummy trench portions 30 may be alternately formed along a predetermined trench array direction. In addition, in the diode portion 80 and the boundary region 90, the dummy trench portions 30 are aligned at predetermined intervals along the predetermined trench array direction. Note that the transistor portion 70 may be constituted only by the gate trench portion 40 without being provided with the dummy trench portion 30.

The gate trench portion 40 of the present example may include two extension portions 41 (portions of the trench which are linear along the extending direction) extending along a trench extending direction perpendicular to the trench array direction and a connection portion 43 connecting the two extension portions 41. The trench extending direction in FIG. 2A is the Y axis direction. Note that the trench extending direction may be the same as or different from the extending direction of the transistor portion 70 and the diode portion 80. The trench extending direction of the present example is the same as the extending direction of the transistor portion 70 and the diode portion 80.

At least a part of the connection portion 43 is preferably provided in a curved shape in top view. By the connection portion 43 connecting end portions of two extension portions 41 in the Y axis direction to each other, it is possible to reduce the electric field strength at the end portions of the extension portions 41.

In the transistor portion 70, the dummy trench portion 30 is provided between the extension portions 41 of the gate trench portion 40. Between the respective extension portions 41, one dummy trench portion 30 may be provided, or a plurality of dummy trench portions 30 may be provided. The dummy trench portion 30 may have a linear shape extending in a predetermined trench extending direction, and may include an extension portion 31 and a connection portion 33 similarly to the gate trench portion 40. The semiconductor device 100 may include both of the linear dummy trench portion 30 having not connection portion 33 and the dummy trench portion 30 having the connection portion 33. A direction in which the extension portion 41 of the gate trench portion 40 or the extension portion 31 of the dummy trench portion 30 extends long in the trench extending direction is defined as the longitudinal direction of the trench portion. The longitudinal direction of the gate trench portion 40 or the dummy trench portion 30 may coincide with the extending direction of the transistor portion 70 and the diode portion 80. In the present example, the extending direction of the transistor portion 70 and the diode portion 80 and the longitudinal direction of the trench portion are the Y axis direction. The trench array direction in which a plurality of the gate trench portions 40 or a plurality of the dummy trench portions 30 are aligned is defined as a short direction of the trench portion. The short direction may coincide with the array direction of the transistor portion 70 and the diode portion 80. In addition, the short direction may be perpendicular to the longitudinal direction. In the present example, the longitudinal direction and the short direction are perpendicular to each other. In the present example, the array direction of the transistor portion 70 and the diode portion 80 and the short direction of the trench portion are the X axis direction.

At the connection portion 43 at a tip of the gate trench portion 40, the gate conductive portion inside the gate trench portion 40 and the gate runner portion 51 are connected to each other. The gate trench portion 40 may be provided so as to protrude to the gate runner portion 51 side with respect to the dummy trench portion 30 in the trench extending direction (Y axis direction). The protruding portion of the gate trench portion 40 is connected to the gate runner portion 51.

A diffusion depth of the well region 17 may be deeper than a depth of the gate trench portion 40 and the dummy trench portion 30. End portions of the gate trench portion 40 and the dummy trench portion 30 in the Y axis direction are provided in the well region 17 in top view. In other words, a bottom of each trench portion in the depth direction is covered with the well region 17 at an end portion of each trench portion in the Y axis direction. With this configuration, the electric field strength on the bottom portion of each trench portion can be reduced.

A mesa portion is provided between the trench portions in the array direction. The mesa portion refers to a region interposed between two adjacent trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion of the present example is provided in the upper surface of the semiconductor substrate 10, so as to extend in the trench extending direction (Y axis direction) along the trench portion.

The main region 75 is a region where a main current flows in the depth direction in the transistor portion 70. The main region 75 includes the emitter region 12 and the contact region 15. An area of the main region 75 may be larger than an area of the boundary region 90.

The boundary region 90 is provided on the diode portion 80 side in the transistor portion 70. That is, in the transistor portion 70, the boundary region 90 is provided adjacent to the diode portion 80 rather than the main region 75. The boundary region 90 may be a region including the dummy trench portion 30 and provided with a collector region 22 on a back surface side of the semiconductor substrate 10. Each of both ends, in the trench array direction, of the mesa portion included in the boundary region 90 may be in contact with the dummy trench portion 30. The trench portions of the boundary region 90 may be all dummy trench portions 30. The boundary region 90 may include the gate trench portion 40. In the boundary region 90 of the present example, the emitter region 12 of a first conductivity type is not provided in the mesa portion on the front surface side of the semiconductor substrate 10. The boundary region 90 may include the base region 14 on the front surface 21. The boundary region 90 may include the emitter region 12 or the contact region 15 on the front surface 21. The boundary region 90 in the present example includes the base region 14 and the contact region 15 on the front surface 21. Note that FIG. 2A illustrates positions of the collector region 22 and the cathode region 82 provided on the back surface side of the semiconductor substrate 10 when projected onto the front surface side.

A mesa portion 71 is a mesa portion provided in the main region 75 of the transistor portion 70. A mesa portion 81 is a mesa portion provided in the diode portion 80. A mesa portion 91 is a mesa portion provided in the boundary region 90. As merely referred to as the mesa portion in the present specification, it may indicate each of the mesa portion 71, the mesa portion 81, or the mesa portion 91. The extension portion of each trench portion may be defined as one trench portion. A region interposed between the two extension portions may be defined as the mesa portion.

Each mesa portion may be provided with the base region 14. In the base region 14 exposed on the front surface 21 of the semiconductor substrate 10 in the mesa portion, a region arranged closest to the gate metal layer 50 is defined as a base region 14-e. In FIG. 2A, the base region 14-e arranged at one end portion of each mesa portion in the trench extending direction is illustrated, but the base region 14-e may also be arranged at the other end portion of each mesa portion. In each mesa portion, a region interposed between the base regions 14-e in top view may be provided with at least one of the emitter region 12 of the first conductivity type or the contact region 15 of the second conductivity type. The emitter region 12 of the present example is the N+ type, and the contact region 15 is the P+ type. The emitter region 12 and the contact region 15 may be provided between the base region 14 and the upper surface of the semiconductor substrate 10 in the depth direction.

The mesa portion 71 of the transistor portion 70 includes the emitter region 12 exposed on the front surface 21 of the semiconductor substrate 10. The emitter region 12 is provided in contact with the gate trench portion 40. The mesa portion 71 may be provided with the contact region 15 exposed on the front surface 21 of the semiconductor substrate 10.

The emitter region 12 is a region of the first conductivity type which is provided in the front surface 21 of the semiconductor substrate 10 and has a doping concentration higher than that of a drift region 18. The drift region 18 will be described later. A doping concentration of the emitter region 12 may be 1E21 cm⁻³ or more and 1E22 cm⁻³ or less. The emitter region 12 of the present example extends from one trench portion in contact with the mesa portion 71 to another trench portion facing the mesa portion in the trench array direction.

The mesa portion 81 of the diode portion 80 is provided with a first conductivity type mesa region 61. The base regions 14-e may be provided at both ends of the first conductivity type mesa region 61 in the trench extending direction. The emitter region 12 is not provided in the front surface 21 of the mesa portion 81, but the emitter region 12 may be provided. The contact region 15 may be provided in the front surface 21 of the mesa portion 81.

The first conductivity type mesa region 61 is a region of the first conductivity type which is provided in the mesa portion between a plurality of trench portions. The first conductivity type mesa region 61 of the present example is provided in the diode portion 80, but may be provided in the boundary region 90, or may be provided in both the diode portion 80 and the boundary region 90. The first conductivity type mesa region 61 of the present example is of the N− type, but is not limited thereto. The first conductivity type mesa region 61 will be described later.

The contact hole 54 is provided above each mesa portion. The contact hole 54 is arranged in a region interposed between the base regions 14-e along the trench extending direction. The contact hole 54 of the present example is provided above each region of the emitter region 12, the contact region 15, the base region 14, and the first conductivity type mesa region 61. The contact hole 54 may not be provided in a region corresponding to the base region 14-e and the well region 17. The contact hole 54 may be arranged at the center in the trench array direction (X axis direction) in the mesa portion.

In the diode portion 80, a region adjacent to the lower surface of the semiconductor substrate 10 is provided with the cathode region 82 of the N+ type. A doping concentration of the cathode region 82 is higher than the doping concentration of the drift region 18. The collector region 22 of the P+ type may be provided in a region, in which the cathode region 82 is not provided, in the lower surface of the semiconductor substrate 10. The cathode region 82 and the collector region 22 are provided between a back surface 23 of the semiconductor substrate 10 and a buffer region 20 to be described later. In FIG. 2A, a boundary 78 between the cathode region 82 and the collector region 22 is indicated by a broken line. The back surface 23 will be described later.

The cathode region 82 is arranged apart from the well region 17 in the trench extending direction. With this configuration, a distance between a region of the P type (well region 17) having a relatively high doping concentration and formed up to a deep position and the cathode region 82 can be secured to improve a breakdown voltage and suppress injection of holes from the well region 17. An end portion of the cathode region 82 of the present example in the trench extending direction is arranged farther from the well region 17 than an end portion of the contact hole 54 in the trench extending direction. In another example, the end portion of the cathode region 82 in the trench extending direction may be arranged between the well region 17 and the contact hole 54.

The mesa portion 91 of the boundary region 90 is provided with the base region 14. The boundary region 90 may include a plurality of the mesa portions 91. The mesa portion 91 may be provided with the contact region 15. The mesa portion 91 of the present example includes the contact region 15 around an end portion of the contact hole 54 in the trench extending direction.

A trench contact portion 58 is provided in a mesa portion between two adjacent trench portions among a plurality of trench portions. The trench contact portion 58 extends from the front surface 21 of the semiconductor substrate 10 in the depth direction of the semiconductor substrate 10. The trench contact portion 58 may be provided to extend from an upper end of the interlayer dielectric film 38 to an inside of the semiconductor substrate 10. The trench contact portion 58 of the present example is provided in the contact hole 54. Since the semiconductor device 100 of the present example includes the trench contact portion 58, it is possible to lower a base resistance during turn-off and improve a latch-up tolerance.

FIG. 2B is a view illustrating an example of an XZ cross section including an a-a′ cross section in FIG. 2A. The XZ cross section, including the a-a′ cross section, is an XZ plane passing through the emitter region 12 in the main region 75. The semiconductor device 100 of the present example includes the semiconductor substrate 10, the interlayer dielectric film 38, the emitter electrode 52, and a collector electrode 24 in the XZ cross section including the a-a′ cross section. The emitter electrode 52 is provided above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region which has remained without another doping region formed in the semiconductor substrate 10. That is, the doping concentration of the drift region 18 may be a doping concentration of the semiconductor substrate 10.

The buffer region 20 is a region of the first conductivity type which is provided on the back surface 23 side of the semiconductor substrate 10 with respect to the drift region 18. The buffer region 20 of the present example is provided closer to the back surface 23 of the semiconductor substrate 10 than a center of the semiconductor substrate 10 in the depth direction. The buffer region 20 in the present example is of the N type as an example. A doping concentration of the buffer region 20 is higher than the doping concentration of the drift region 18. The buffer region 20 may function as a field stop layer which prevents a depletion layer expanding from a lower surface side of the base region 14 from reaching the collector region 22 of the second conductivity type and the cathode region 82 of the first conductivity type.

The collector region 22 and the cathode region 82 are provided in the back surface 23 of the semiconductor substrate 10. The collector region 22 is provided below the buffer region 20 in the transistor portion 70. The cathode region 82 is provided below the buffer region 20 in the diode portion 80. The boundary 78 between the collector region 22 and the cathode region 82 may be a boundary between the transistor portion 70 and the diode portion 80.

The collector electrode 24 is formed on the back surface 23 of the semiconductor substrate 10. The collector electrode 24 is formed of a conductive material such as metal. At least a partial region of the collector electrode 24 may be formed of metal such as aluminum (AI) or a metal alloy such as an aluminum-silicon alloy (AlSi) or an aluminum-silicon-copper alloy (AlSiCu).

The base region 14 is a region of the second conductivity type which is provided above the drift region 18 in the mesa portion 71. The base region 14 may also be provided in the mesa portion 91. The base region 14 is provided in contact with the gate trench portion 40. The base region 14 may be provided in contact with the dummy trench portion 30.

An accumulation region 16 is provided above the drift region 18. That is, the accumulation region 16 is provided on the front surface 21 side of the semiconductor substrate 10 with respect to the drift region 18. The accumulation region 16 is a region of the first conductivity type which has a doping concentration higher than that of the drift region 18. The accumulation region 16 of the present example is of the N+ type as an example. The doping concentration of the accumulation region 16 may be 1E16 cm⁻³ or more and 1E18 cm⁻³ or less. The accumulation region 16 is provided in the mesa portion 71. The accumulation region 16 may also be provided in the mesa portion 81 and the mesa portion 91.

In addition, the accumulation region 16 is provided in contact with the gate trench portion 40. The accumulation region 16 may or may not be in contact with the dummy trench portion 30. The doping concentration of the accumulation region 16 is higher than the doping concentration of the drift region 18. Providing the accumulation region 16 can increase a carrier injection enhancement effect (IE effect) to reduce an on-voltage of the transistor portion 70.

One or more gate trench portions 40 and one or more dummy trench portions 30 are provided in the front surface 21. Each trench portion is provided from the front surface 21 to the drift region 18. In a region provided with at least any of the emitter region 12, the base region 14, the contact region 15, or the accumulation region 16, each trench portion also penetrates these regions to reach the drift region 18. A configuration in which the trench portion penetrates the doping region is not limited to a configuration which is manufactured in an order of forming the doping region and then forming the trench portion. The configuration in which the trench portion penetrates the doping region includes a configuration in which the trench portions are formed and then the doping region is formed between the trench portions.

The gate trench portion 40 includes a gate trench, a gate dielectric film 42, and a gate conductive portion 44 which are formed on the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region facing the base region 14 with the gate dielectric film 42 interposed therebetween. When a predetermined voltage is applied to the gate conductive portion 44, a channel of electrons by an inversion layer is formed in a surface layer of an interface which is in contact with the gate trench in the base region 14.

The dummy trench portion 30 may have a same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed to cover the inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 of the present example is provided on the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to penetrate the interlayer dielectric film 38.

A front-surface electrode portion 200 is provided above the front surface 21 of the semiconductor substrate 10. The front-surface electrode portion 200 includes the emitter electrode 52, a barrier metal portion 220, and a plug portion 230. The front-surface electrode portion 200 may include a silicide layer 210 described later. The front-surface electrode portion 200 may include the trench contact portion 58. The front-surface electrode portion 200 may be in ohmic contact with a plug region 13 described later.

The barrier metal portion 220 is provided on a side wall and a bottom surface of the contact hole 54. The barrier metal portion 220 may be provided on the entire bottom surface of the contact hole 54. A material of the barrier metal portion 220 may be titanium and/or a titanium compound. The barrier metal portion 220 may contain Ti or TiN.

The plug portion 230 is provided inside the barrier metal portion 220 in the contact hole 54. A material of the plug portion 230 may be tungsten. The material of the plug portion 230 may be the same as the material of the emitter electrode 52. That is, the plug portion 230 may be a portion of the emitter electrode 52 embedded in the contact hole 54.

The semiconductor device 100 of the present example does not include a lifetime control unit having a lifetime killer, but may include the lifetime control unit. The semiconductor device 100 may include a lifetime killer region on the front surface 21 side with respect to the center of the semiconductor substrate 10 in the depth direction, or may include the lifetime killer region on the back surface 23 side with respect to the center of the semiconductor substrate 10 in the depth direction.

The first conductivity type mesa region 61 is a region of the first conductivity type which is in contact with the plug region 13 in the mesa portion between the plurality of trench portions. The first conductivity type mesa region 61 of the present example is in contact with the plug region 13 in the mesa portion 81. The first conductivity type mesa region 61 in the present example is the drift region 18. The first conductivity type mesa region 61 may be a region having a doping concentration different from that of the drift region 18.

The plug region 13 is a region of the second conductivity type which is provided above the drift region 18 and has a doping concentration higher than that of the base region 14. The plug region 13 may have a doping concentration higher than that of the contact region 15. The plug region 13 of the present example is the P++ type, but is not limited thereto.

The plug region 13 may be provided in the semiconductor substrate 10 and may be in contact with the front-surface electrode portion 200. The plug region 13 of the present example is provided below the trench contact portion 58. The plug region 13 may be in contact with the trench contact portion 58. The plug region 13 of the present example is in contact with a bottom surface of the trench contact portion 58. The plug region 13 may be in contact with a side surface of the trench contact portion 58. The plug region 13 may cover the entire side surface of the trench contact portion 58. The plug region 13 of the present example covers the entire side surface of the trench contact portion 58 in the mesa portion 81. The plug region 13 of the mesa portion 81 covers the side surface and the bottom surface of the trench contact portion 58 at a depth position deeper than the front surface 21 of the semiconductor substrate 10. The plug region 13 may not cover the entire side surface of the trench contact portion 58 in the mesa portion 71. The plug region 13 may cover the entire side surface of the trench contact portion 58 in the mesa portion 91.

The plug region 13 may be continuously provided on the bottom surface of the trench contact portion 58 to extend in the trench extending direction. The plug region 13 may be provided on the entire bottom surface of the trench contact portion 58. The plug region 13 may be discretely provided in the trench extending direction on the bottom surface of the trench contact portion 58. The plug region 13 may be provided in at least one of the main region 75, the diode portion 80, or the boundary region 90. The plug region 13 of the present example is provided in each of the main region 75, the diode portion 80, and the boundary region 90.

The plug region 13 may be in contact with the first conductivity type mesa region 61 in the mesa portion 81. The plug region 13 may be in contact with the emitter region 12 and the base region 14 in the mesa portion 71. A lower end of the plug region 13 may be deeper than a lower end of the emitter region 12 and shallower than a lower end of the base region 14. The plug region 13 may be in contact with the base region 14 in the mesa portion 91.

A lower end of the trench contact portion 58 may be deeper than the lower end of the emitter region 12. The lower end of the trench contact portion 58 may be shallower than the lower end of the base region 14. The lower end of the trench contact portion 58 may be shallower than an upper end of the accumulation region 16. A shape of the trench contact portion 58 may be identical or vary across the main region 75, the diode portion 80, and the boundary region 90.

FIG. 2C is a view illustrating an example of an XZ cross section including a b-b′ cross section in FIG. 2A. The XZ cross section, including the b-b′ cross section, is the XZ plane passing through the contact region 15 in the main region 75. In the present example, differences from the a-a′ cross section of FIG. 2B passing through the emitter region 12 will be described in particular. Other features may be the same as those of the a-a′ cross section in FIG. 2B.

A lower end of the contact region 15 may be deeper than the lower end of the emitter region 12. The contact region 15 may be in contact with the plug region 13 and the base region 14 in the mesa portion 71.

The plug region 13 may be in contact with the contact region 15 and the base region 14 in the mesa portion 71. The lower end of the plug region 13 may be deeper than the lower end of the contact region 15 and shallower than the lower end of the base region 14.

The lower end of the trench contact portion 58 may be deeper than the lower end of the contact region 15. The lower end of the trench contact portion 58 may be shallower than the lower end of the base region 14. The lower end of the trench contact portion 58 may be shallower than the upper end of the accumulation region 16. The shape of the trench contact portion 58 in the XZ cross section passing through the contact region 15 may be the same as the shape of the trench contact portion 58 in the XZ cross section passing through the emitter region 12.

The mesa portion 81 may be the same as the mesa portion 81 in the a-a′ cross section of FIG. 2B. The mesa portion 91 may be the same as the mesa portion 91 in the a-a′ cross section of FIG. 2B.

FIG. 2D is an enlarged view of an XZ cross section passing through the mesa portion 81. This drawing illustrates the mesa portion 81 interposed between two adjacent dummy trench portions 30. The front-surface electrode portion 200 includes the silicide layer 210, the barrier metal portion 220, the plug portion 230, and the emitter electrode 52.

The silicide layer 210 is in contact with the semiconductor substrate 10. When the semiconductor substrate 10 is silicon, the silicide layer 210 may be a layer formed by the barrier metal portion 220 reacting with the semiconductor substrate 10 to be silicided. The silicide layer 210 is provided on both the bottom surface and the side surface of the trench contact portion 58. The silicide layer 210 of the present example is in contact with the plug region 13. The silicide layer 210 may not be provided in a region not in contact with the semiconductor substrate 10. A material of the buffer region 20 in the present example is TiSi, but is not limited thereto.

The barrier metal portion 220 is in contact with the silicide layer 210. The barrier metal portion 220 may contain a material which reacts with Si of the semiconductor substrate 10 to be silicided. The barrier metal portion 220 may contain Ti. The barrier metal portion 220 of the present example includes a first barrier metal layer 221 and a second barrier metal layer 222.

The first barrier metal layer 221 is provided on the side surface of the trench contact portion 58. The first barrier metal layer 221 may be in contact with the silicide layer 210 provided on the side surface and the bottom surface of the trench contact portion 58. A part of the first barrier metal layer 221 may be in contact with the interlayer dielectric film 38 on the side surface of the trench contact portion 58. A material of the first barrier metal layer 221 in the present example is Ti.

The second barrier metal layer 222 is provided inside the first barrier metal layer 221 in the trench contact portion 58. The second barrier metal layer 222 is provided close to the bottom surface and the side surface of the trench contact portion 58. The second barrier metal layer 222 may be in contact with the first barrier metal layer 221. A material of the second barrier metal layer 222 in the present example is TiN.

The plug portion 230 is provided inside the barrier metal portion 220 in the trench contact portion 58. The plug portion 230 of the present example is provided inside the second barrier metal layer 222 in the trench contact portion 58. The plug portion 230 of the present example is in contact with the second barrier metal layer 222. The plug portion 230 may be formed using a method and a material capable of filling an inside of the contact hole 54. A material of the plug portion 230 of the present example is tungsten.

As described above, the semiconductor device 100 may have a stacked structure of the semiconductor substrate 10, the silicide layer 210, the first barrier metal layer 221, the second barrier metal layer 222, and the plug portion 230. In an example, the semiconductor device 100 has a stacked structure of a Si substrate, a TiSi layer, a Ti layer, a TiN layer, and a W layer. A barrier height between the front-surface electrode portion 200 and the semiconductor substrate 10 may be adjusted by changing a material of the front-surface electrode portion 200. The barrier height between the front-surface electrode portion 200 and the semiconductor substrate 10 may be 0.6 eV or more and 1.0 eV or less.

A depth D58 indicates a distance from the front surface 21 to the lower end of the trench contact portion 58 in the depth direction of the semiconductor substrate 10. By increasing the depth D58, an injection amount of holes from the transistor portion 70 to the diode portion 80 is suppressed to easily reduce a reverse recovery loss Err.

The front-surface electrode portion 200 is separated from the first conductivity type mesa region 61. That is, the silicide layer 210 is covered with the plug region 13 and is separated from the first conductivity type mesa region 61. With this configuration, initial leakage of currents can be easily suppressed.

A mesa width Wm is a width of the mesa portion in the trench array direction. The mesa width Wm in the present example indicates a mesa width of the mesa portion 81. A trench width Wt is a width in the trench array direction of an arbitrary trench portion among a plurality of trench portions. The trench width Wt of the present example indicates a trench width of the dummy trench portion 30. The mesa width Wm in the present example is larger than the trench width Wt, but may be smaller than the trench width Wt or may be the same as the trench width Wt.

FIG. 2E illustrates an example of a YZ cross section including a c-c′ cross section in FIG. 2A. The YZ cross section, including the c-c′ cross section, is a YZ plane passing through the mesa portion 81 of the diode portion 80. The c-c′ cross section is a cross section passing through the contact hole 54.

The base region 14 extends, in the trench extending direction, from an end portion of the well region 17 toward the end portion of the contact hole 54 provided in the interlayer dielectric film 38. The base region 14 may be separated from the plug region 13 in the trench extending direction. The plug region 13 of the present example is continuously provided below the trench contact portion 58 to extend in the trench extending direction. The plug region 13 may be provided below the trench contact portion 58 to be separated in the trench extending direction. The plug region 13 may cover the side surface of the end portion of the trench contact portion 58 in the trench extending direction.

A distance L0 is a distance between the base region 14 and the end portion of the contact hole 54 in the trench extending direction. The distance L0 is greater than 0 μm and may be within a width Wd of a depletion layer expanding from the base region 14 toward the drift region 18.

A distance L1 is a distance between the end portion of the contact hole 54 and the cathode region 82 in the trench extending direction. By setting the distance L1 to an appropriate size, a breakdown voltage at the end portion of the contact hole 54 can be improved, and a reliability can be improved.

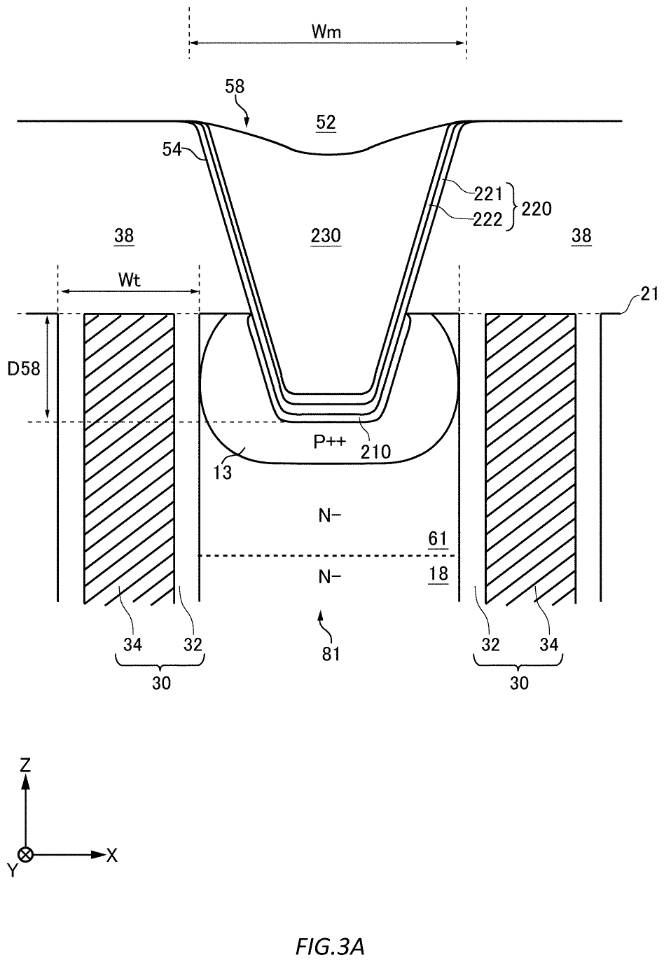

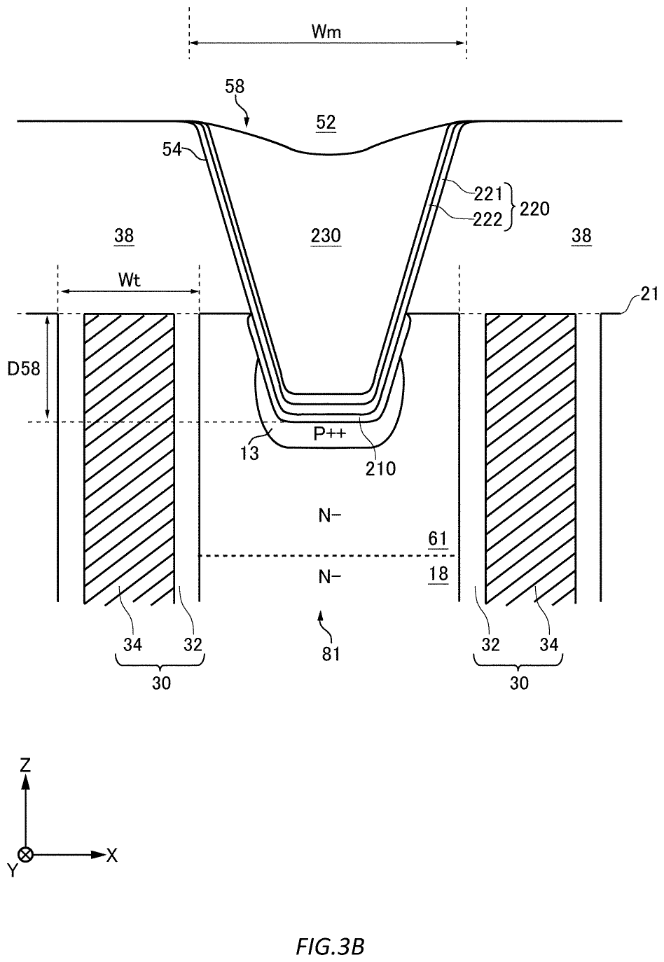

FIG. 3A is an enlarged view of a modification of the XZ cross section passing through the mesa portion 81. The mesa portion 81 of the present example is different from the mesa portion 81 of FIG. 2D in a position where the plug region 13 is provided. In the present example, differences from the mesa portion 81 in FIG. 2D will be described in particular, and other features may be the same as those of the mesa portion 81 in FIG. 2D. In the present example, the mesa portion 81 of the diode portion 80 will be described, but the position where the plug region 13 is provided may be applied to the mesa portion 91 of the boundary region 90.

The plug region 13 is in contact with an adjacent trench portion among a plurality of trench portions. The plug region 13 of the present example is in contact with the dummy trench portion 30, but may be in contact with the gate trench portion 40. The plug region 13 of the present example is in contact with the dummy trench portions 30 at both ends in the trench array direction. One end of the plug region 13 in the trench array direction may be in contact with the dummy trench portion 30, and the other end thereof may be in contact with the gate trench portion 40. The plug region 13 may be in contact with the gate trench portions 40 at both ends in the trench array direction. The first conductivity type mesa region 61 may be provided above a location where the plug region 13 and the trench portion are in contact with each other. A lower surface of the plug region 13 may be in contact with the first conductivity type mesa region 61.

In the semiconductor device 100 of the present example, the plug region 13 is formed to extend toward the trench portion, so that a depletion layer is easily diffused in the trench array direction. With this configuration, the semiconductor device 100 of the present example can suppress reach-through of the depletion layer to the front-surface electrode portion 200.

FIG. 3B is an enlarged view of a modification of the XZ cross section passing through the mesa portion 81. The mesa portion 81 of the present example is different from the mesa portion 81 of FIG. 2D in the position where the plug region 13 is provided. In the present example, differences from the mesa portion 81 in FIG. 2D will be described in particular, and other features may be the same as those of the mesa portion 81 in FIG. 2D. In the present example, the mesa portion 81 of the diode portion 80 will be described, but the position where the plug region 13 is provided may be applied to the mesa portion 91 of the boundary region 90.

The plug region 13 covers a part of the side surface and the bottom surface of the trench contact portion 58 at a depth position deeper than the front surface 21 of the semiconductor substrate 10. That is, the plug region 13 may not be in contact with a part of the side surface of the trench contact portion 58. A proportion of a region, which is covered with the plug region 13, of the side surface of the trench contact portion 58 to the side surface of the trench contact portion 58 may be 30% or more, 50% or more, 80% or less, 90% or less, or less than 100%. The plug region 13 of the present example is separated from the dummy trench portion 30, but may be in contact with the dummy trench portion 30.

The trench contact portion 58 may be in contact with the first conductivity type mesa region 61 and the plug region 13 on its side surface. In the present example, the silicide layer 210 is in contact with the first conductivity type mesa region 61 and the plug region 13 on the side surface of the trench contact portion 58. The trench contact portion 58 may form a Schottky junction with the first conductivity type mesa region 61 on its side surface.

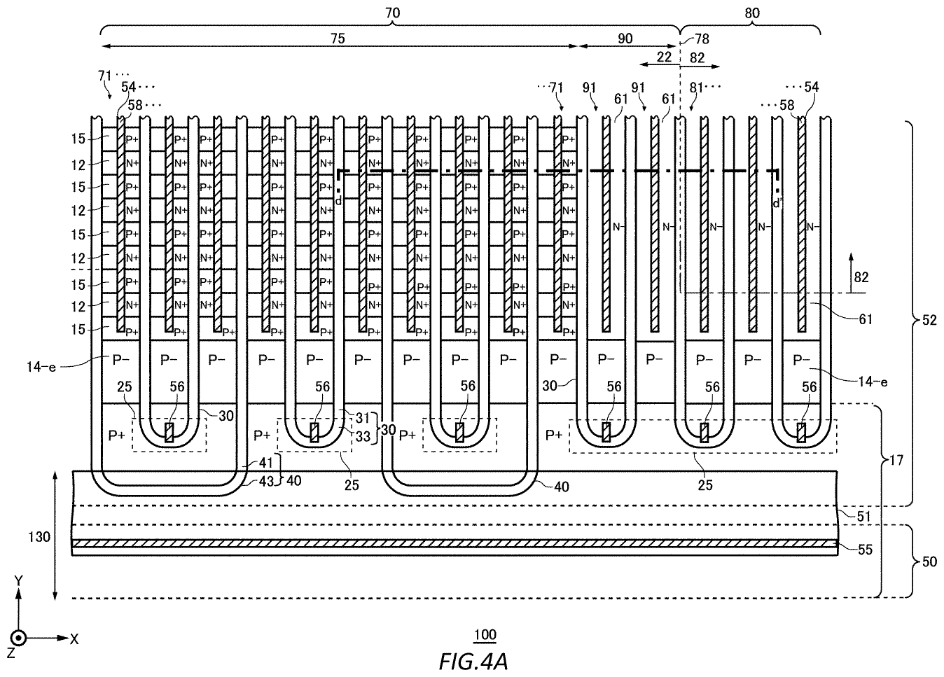

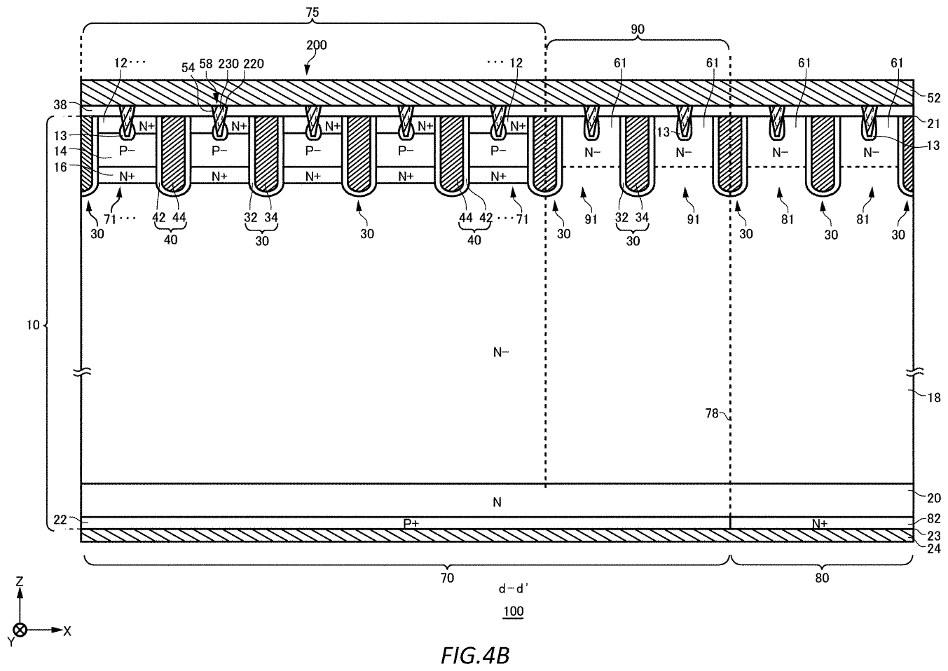

FIG. 4A is a top view of a modification of the semiconductor device 100. In the semiconductor device 100 of the present example, a structure of the boundary region 90 is different from that of the boundary region 90 in FIG. 2A. In the present example, differences from the semiconductor device 100 in FIG. 2A will be described in particular. Other features may be the same as those of the semiconductor device 100 in FIG. 2A.

The boundary region 90 does not include the base region 14 in a region where the contact hole 54 for connecting the semiconductor substrate 10 to the front-surface electrode portion 200 is provided. The boundary region 90 in the present example includes the first conductivity type mesa region 61 exposed on the front surface 21 of the semiconductor substrate 10. The first conductivity type mesa region 61 may be provided in a region where the contact hole 54 is provided in the mesa portion 91 of the boundary region 90. The boundary region 90 may include the base region 14-e at an end portion of the mesa portion 91 in the trench extending direction.

FIG. 4B is a view illustrating an example of an XZ cross section including a d-d′ cross section in FIG. 4A. The XZ cross section, including the d-d′ cross section, is the XZ plane passing through the emitter region 12 in the main region 75. A cross-sectional structure of the mesa portion 91 may be the same as that of the mesa portion 91 on the XZ plane passing through the contact region 15 in the main region 75.

The mesa portion 91 includes the plug region 13 and the first conductivity type mesa region 61. The first conductivity type mesa region 61 may be the drift region 18. The mesa portion 91 of the present example does not include the base region 14 below the contact hole 54. The plug region 13 of the mesa portion 91 may be in contact with the first conductivity type mesa region 61. A structure of the mesa portion 91 may be the same as a structure of the mesa portion 81.

In the semiconductor device 100 of the present example, by providing the first conductivity type mesa region 61 also in the boundary region 90 in addition to the diode portion 80, the injection amount of holes from the transistor portion 70 to the diode portion 80 is suppressed to more easily reduce the reverse recovery loss Err. A width of the boundary region 90 in the trench array direction may be determined in consideration of the injection amount of holes from the transistor portion 70 to the diode portion 80.

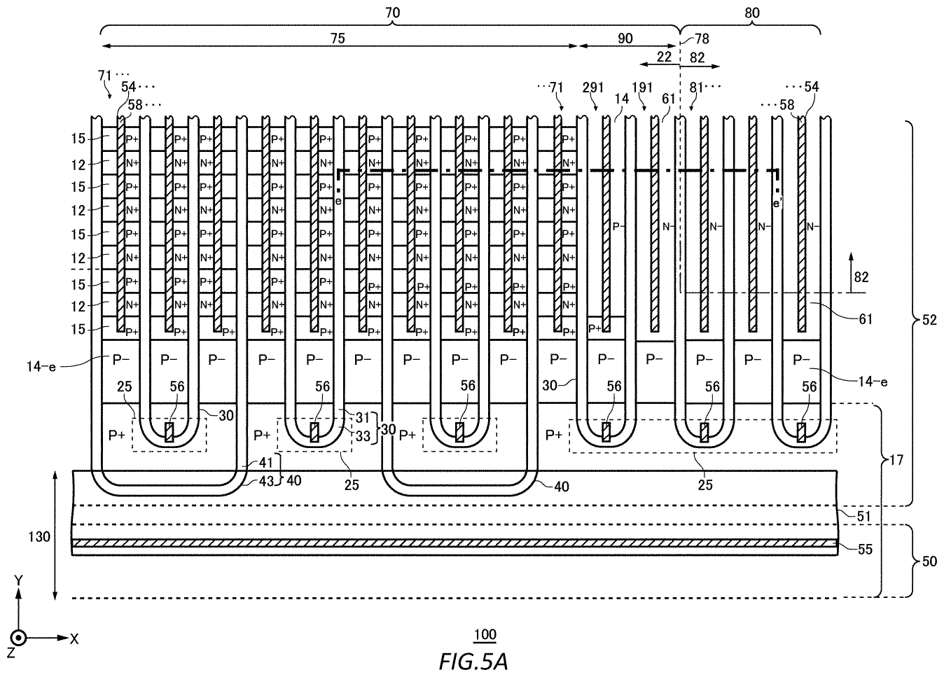

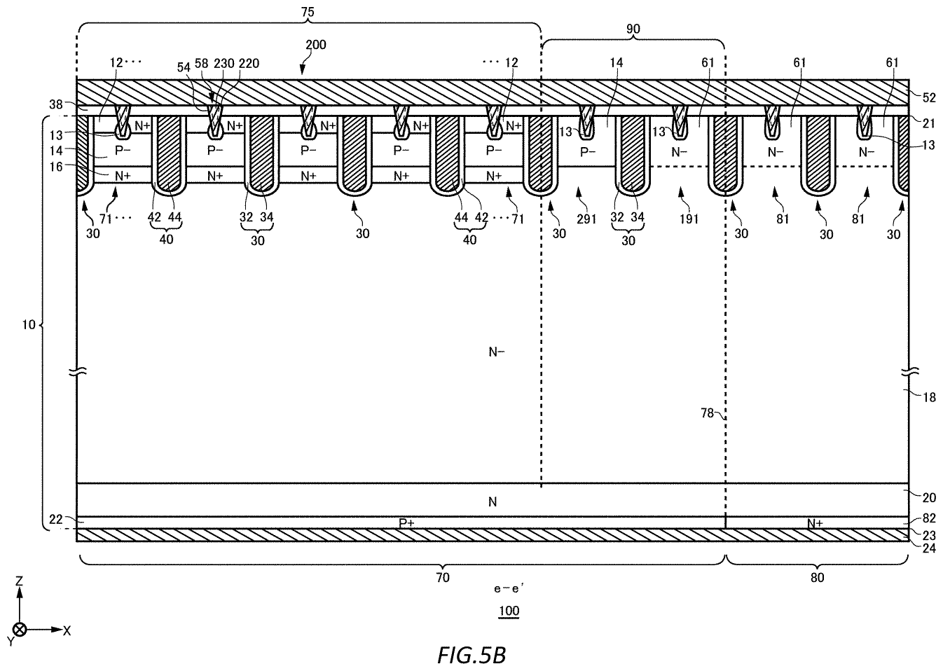

FIG. 5A is a top view of a modification of the semiconductor device 100. In the semiconductor device 100 of the present example, the structure of the boundary region 90 is different from that of the boundary region 90 of FIG. 2A. In the present example, differences from the semiconductor device 100 in FIG. 2A will be described in particular. Other features may be the same as those of the semiconductor device 100 in FIG. 2A.

The boundary region 90 of the present example includes a first boundary mesa portion 191 and a second boundary mesa portion 291 as examples of the mesa portion 91. The first boundary mesa portion 191 and the second boundary mesa portion 291 may differ in an occupation proportion of the region of the second conductivity type in the mesa portion 91. The second boundary mesa portion 291 may have a larger occupation proportion of the region of the second conductivity type than the first boundary mesa portion 191.

The first boundary mesa portion 191 is a region where the base region 14 is not included in a region where the contact hole 54 for connecting the semiconductor substrate 10 to the front-surface electrode portion 200 is provided. However, the first boundary mesa portion 191 may include the base region 14-e provided at the end portion in the trench extending direction. The first boundary mesa portion 191 may be provided adjacent to the diode portion 80. The first boundary mesa portion 191 of the present example is in contact with the dummy trench portion 30, but may be in contact with the gate trench portion 40.

The second boundary mesa portion 291 is provided closer to the main region 75 than the first boundary mesa portion 191. The second boundary mesa portion 291 may be provided between the first boundary mesa portion 191 and the main region 75. The second boundary mesa portion 291 is a region where the base region 14 is included in the region where the contact hole 54 for connecting the semiconductor substrate 10 and the front-surface electrode portion 200 is provided. The second boundary mesa portion 291 of the present example is in contact with the dummy trench portion 30, but may be in contact with the gate trench portion 40.

In the semiconductor device 100 of the present example, the base region 14 of the second conductivity type is omitted in the first boundary mesa portion 191 close to the diode portion 80. In the semiconductor device 100, reducing the occupation proportion of the region of the second conductivity type in the first boundary mesa portion 191 close to the diode portion 80 can suppress hole injection and reduce the reverse recovery loss Err.

FIG. 5B is a view illustrating an example of an XZ cross section including an e-e′ cross section in FIG. 5A. The XZ cross section, including the e-e′ cross section, is the XZ plane passing through the emitter region 12 in the main region 75. The cross-sectional structure of the mesa portion 91 may be the same as that of the mesa portion 91 on the XZ plane passing through the contact region 15 in the main region 75.

The first boundary mesa portion 191 includes the plug region 13 and the first conductivity type mesa region 61. The first boundary mesa portion 191 may include the drift region 18. The first conductivity type mesa region 61 may be the drift region 18. The first boundary mesa portion 191 does not include the base region 14 below the contact hole 54. The plug region 13 of the first boundary mesa portion 191 may be in contact with the first conductivity type mesa region 61. That is, a structure of the first boundary mesa portion 191 may be the same as the structure of the mesa portion 81.

The second boundary mesa portion 291 includes the plug region 13 and the base region 14. The second boundary mesa portion 291 of the present example includes the base region 14 below the contact hole 54. The plug region 13 of the second boundary mesa portion 291 may be in contact with the base region 14. The second boundary mesa portion 291 may include the drift region 18.

The boundary region 90 may include a plurality of the first boundary mesa portions 191 and may include a plurality of the second boundary mesa portions 291. In the boundary region 90 of the present example, a number of the first boundary mesa portions 191 is the same as a number of the second boundary mesa portions 291, but the number of the first boundary mesa portions 191 may have different from the number of the second boundary mesa portions 291. The number of the first boundary mesa portions 191 may be greater than or less than the number of the second boundary mesa portions 291. A ratio between the number of the first boundary mesa portions 191 and the number of the second boundary mesa portions 291 may be determined in consideration of the injection amount of holes from the transistor portion 70 to the diode portion 80.

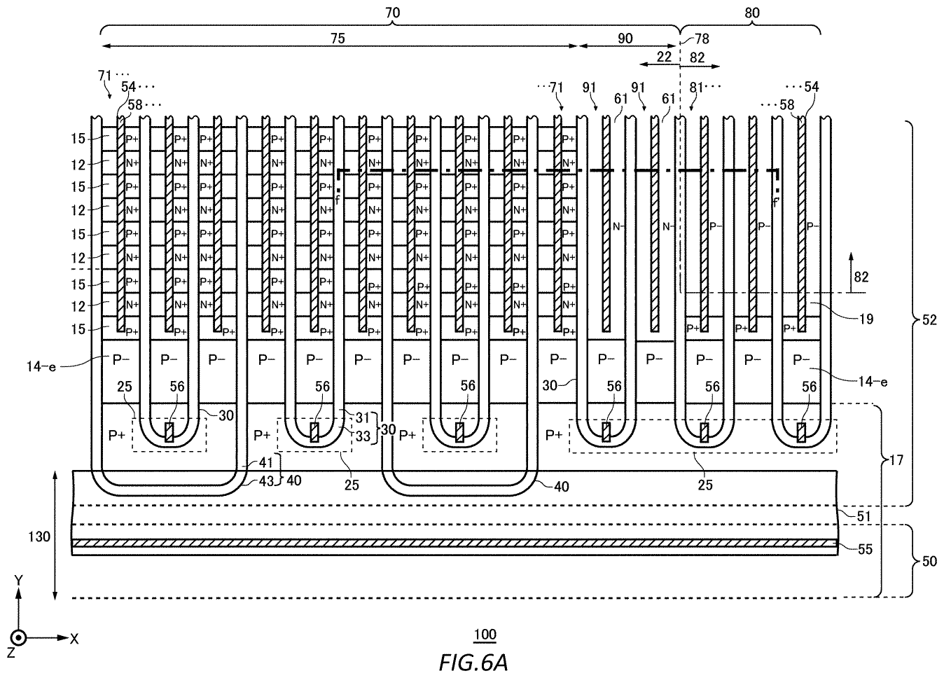

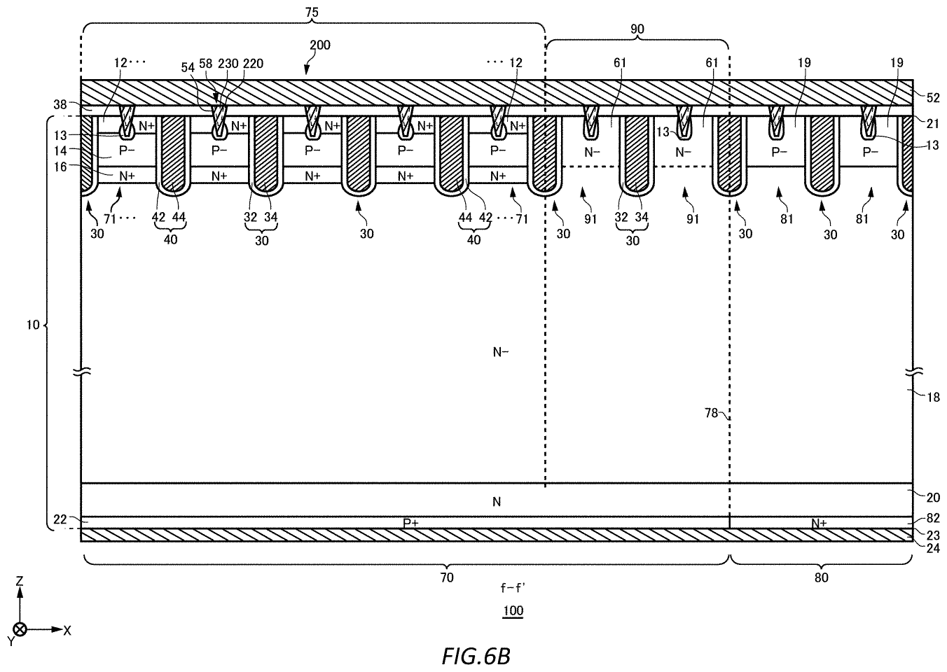

FIG. 6A is a top view of a modification of the semiconductor device 100. The semiconductor device 100 of the present example is different in structures of the diode portion 80 and the boundary region 90 from the semiconductor device 100 of FIG. 2A. In the present example, differences from the semiconductor device 100 in FIG. 2A will be described in particular. Other features may be the same as those of the semiconductor device 100 in FIG. 2A. The diode portion 80 of the present example has an anode region 19.

The main region 75 includes the base region 14 of the second conductivity type which is provided above the drift region 18. On the other hand, the boundary region 90 does not include the base region 14 in a region where the contact hole 54 for connecting the semiconductor substrate 10 to the front-surface electrode portion 200 is provided. The first conductivity type mesa region 61 may be provided in a region where the contact hole 54 is provided in the mesa portion 91 of the boundary region 90. The boundary region 90 may include the base region 14-e at the end portion of the mesa portion 91 in the trench extending direction.

The anode region 19 is a region of the second conductivity type which is provided above the drift region 18. The anode region 19 is provided in the mesa portion 81. The anode region 19 may be in contact with the dummy trench portion 30. The anode region 19 of the present example is provided in the mesa portion 81 to extend in the trench array direction from one adjacent dummy trench portion 30 to another adjacent dummy trench portion 30. The anode region 19 may be provided in contact with the gate trench portion 40. A depth of the anode region 19 may be deeper, shallower, or equal to a depth of the base region 14 in the depth direction of the semiconductor substrate 10. The depth of the anode region 19 in the present example is equal to the depth of the base region 14.

A doping concentration of the anode region 19 may be the same as that of the base region 14, may be lower than that of the base region 14, and may be higher than that of the base region 14. A maximum value of the doping concentration of the anode region 19 may be lower than, may be higher than, or may be equal to a maximum value of the doping concentration of the base region 14. The maximum value of the doping concentration of the anode region 19 of the present example is the same as the maximum value of the doping concentration of the base region 14. An integrated value obtained by integrating the doping concentration of the anode region 19 along the depth direction of the semiconductor substrate 10 may be less than, may be greater than, or may be equal to an integrated value obtained by integrating the doping concentration of the base region 14. The integrated value of the doping concentration of the anode region 19 of the present example is the same as the integrated value of the doping concentration of the base region 14. The anode region 19 in the present example is the P− type.

FIG. 6B is a view illustrating an example of an XZ cross section including an f-f′ cross section in FIG. 6A. The XZ cross section, including the f-f′ cross section, is the XZ plane passing through the emitter region 12 in the main region 75. The cross-sectional structure of the mesa portion 91 may be the same as that of the mesa portion 91 on the XZ plane passing through the contact region 15 in the main region 75.

The mesa portion 81 includes the plug region 13 and the anode region 19. The mesa portion 81 may include the drift region 18. The plug region 13 of the mesa portion 81 may be in contact with the anode region 19. A lower end of the anode region 19 may be at a depth position same as that of the lower end of the base region 14, or may be at a depth position different therefrom.

The mesa portion 91 includes the plug region 13 and the first conductivity type mesa region 61. The mesa portion 91 may include the drift region 18. The first conductivity type mesa region 61 may be the drift region 18. The mesa portion 91 does not include the base region 14 and the anode region 19 below the contact hole 54. The plug region 13 of the mesa portion 91 may be in contact with the first conductivity type mesa region 61.

The region of the first conductivity type of the boundary region 90 may occupy 50% or more of the mesa portion 91 at a depth position shallower than that of the lower end of the base region 14. That is, the first conductivity type mesa region 61 may occupy 50% or more of a sum of the regions where the first conductivity type mesa region 61 and the plug region 13 are provided. When the first conductivity type mesa region 61 is the drift region 18, a lower end of the first conductivity type mesa region 61 may be defined as a position equal to the lower end of the base region 14.

In the semiconductor device 100 of the present example, by reducing the region of the second conductivity type in the boundary region 90, the injection amount of holes from the transistor portion 70 to the diode portion 80 is suppressed to easily reduce the reverse recovery loss Err.

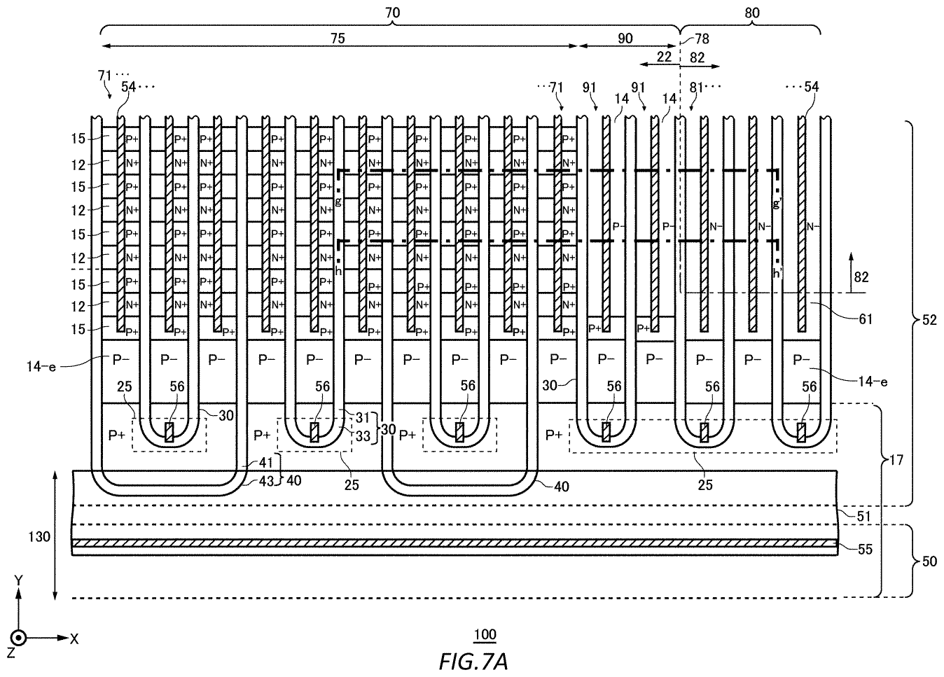

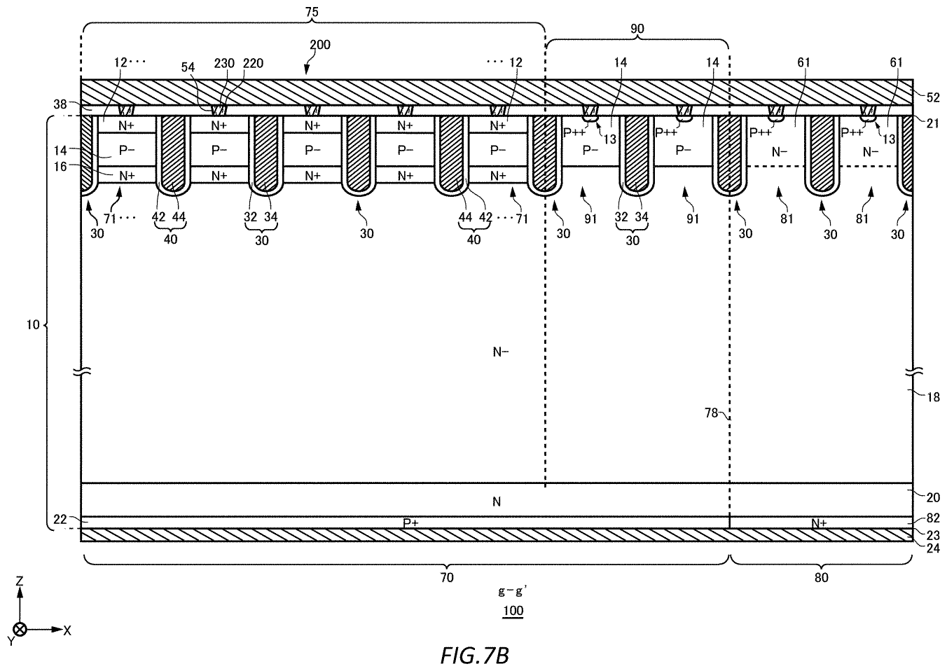

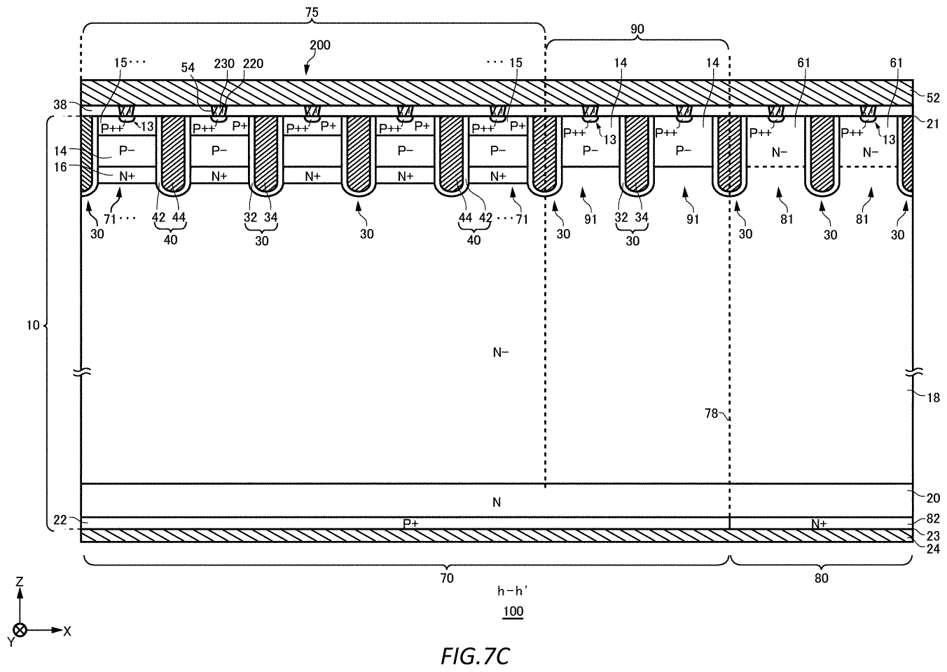

FIG. 7A is a top view of a modification of the semiconductor device 100. The semiconductor device 100 of the present example is different from the semiconductor device 100 of FIG. 2A in that the trench contact portion 58 is not provided. In the present example, differences from the semiconductor device 100 in FIG. 2A will be described in particular. Other features may be the same as those of the semiconductor device 100 in FIG. 2A.

FIG. 7B is a view illustrating an example of an XZ cross section including a g-g′ cross section in FIG. 7A. The XZ cross section, including the g-g′ cross section, is the XZ plane passing through the emitter region 12 in the main region 75. The front-surface electrode portion 200 is in contact with the semiconductor substrate 10 on the front surface 21. The semiconductor device 100 of the present example is different from the semiconductor device 100 including the trench contact portion 58 in that the contact hole 54 does not extend in the depth direction of the semiconductor substrate 10.

The plug region 13 is provided in the mesa portion 81. The plug region 13 is in contact with the front-surface electrode portion 200 on the front surface 21. The plug region 13 is provided below the contact hole 54. The plug region 13 may be provided so as to cover the lower surface of the front-surface electrode portion 200 provided in the contact hole 54. The plug region 13 may be in contact with the first conductivity type mesa region 61. The plug region 13 may be provided in the mesa portion 91. The plug region 13 may not be provided in a region where the emitter region 12 is provided in the mesa portion 71.

The first conductivity type mesa region 61 may be provided to be exposed on the front surface 21 of the semiconductor substrate 10. The first conductivity type mesa region 61 in the present example is the drift region 18. However, the first conductivity type mesa region 61 may be a region of the first conductivity type which has a doping concentration different from that of the drift region 18. The first conductivity type mesa region 61 may be provided in the mesa portion 91.

A structure in which the front-surface electrode portion 200 is connected to the semiconductor substrate 10 on the front surface 21 may be appropriately applied to the semiconductor device 100 of another embodiment. As described above, whether or not to provide the trench contact portion 58 may be appropriately changed.

FIG. 7C is a view illustrating an example of an XZ cross section including an h-h′ cross section in FIG. 7A. The XZ cross section, including the h-h′ cross section, is the XZ plane passing through the contact region 15 in the main region 75. The front-surface electrode portion 200 is in contact with the semiconductor substrate 10 on the front surface 21. In the present example, differences from the g-g′ cross section of FIG. 7B will be described in particular. Other features may be the same as those of the g-g′ cross section of FIG. 7B.

The plug region 13 is also provided in a region where the contact region 15 is provided in the mesa portion 71. The plug region 13 is provided below the contact hole 54. The plug region 13 may be provided so as to cover the lower surface of the front-surface electrode portion 200 provided in the contact hole 54. A doping concentration of the plug region 13 may be higher than a doping concentration of the contact region 15. The plug region 13 may be in contact with the contact region 15. The lower end of the plug region 13 may be shallower than the lower end of the contact region 15. The plug region 13 may also be provided in the mesa portion 81 and the mesa portion 91.

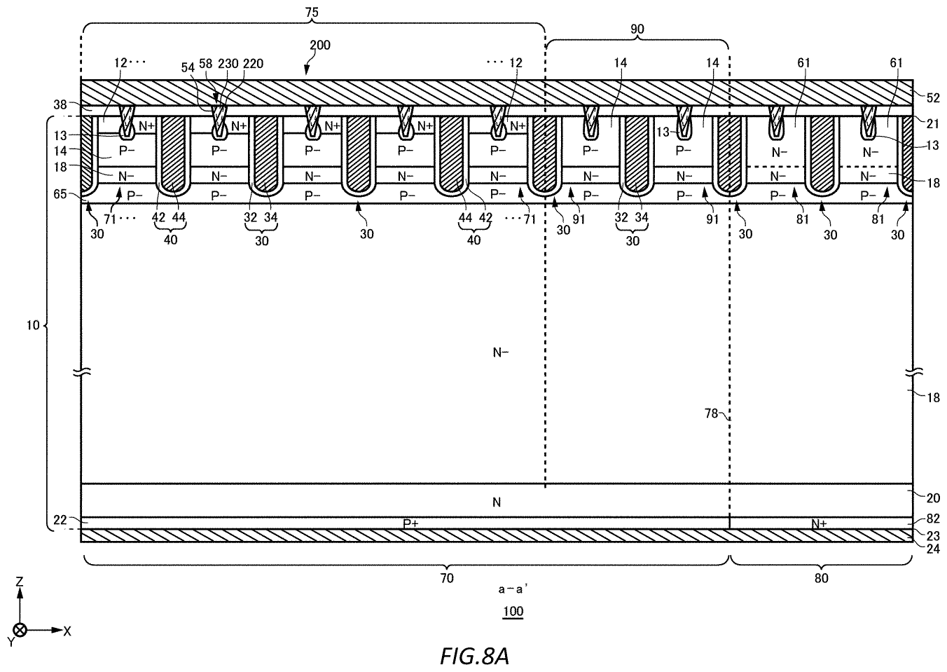

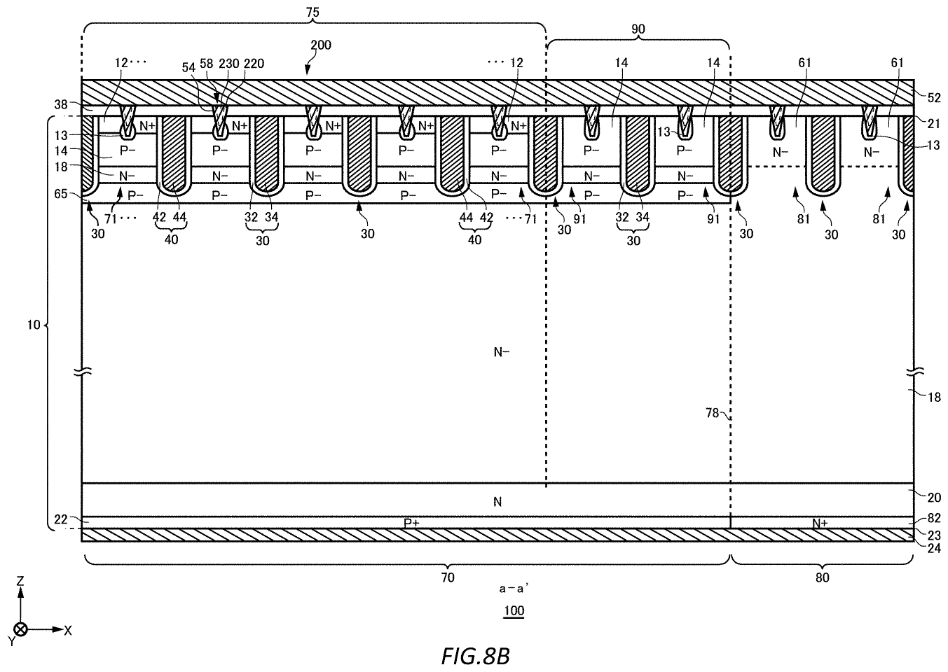

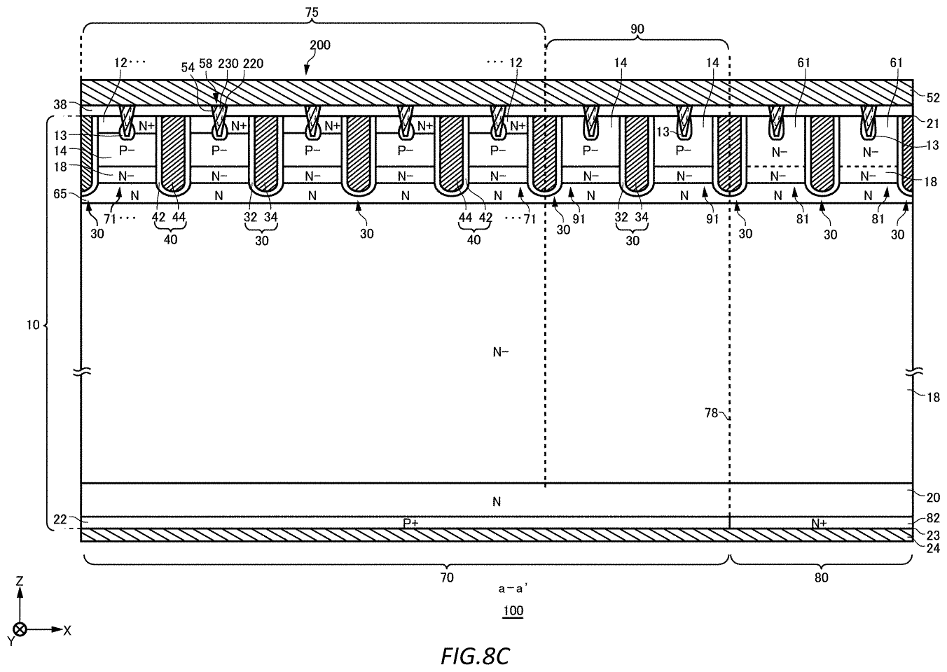

FIG. 8A is a view illustrating a modification of the XZ cross section including the a-a′ cross section in FIG. 2A. The semiconductor device 100 of the present example is different from the a-a′ cross section of FIG. 2B in that a trench bottom region 65 is included. In the present example, differences from the a-a′ cross section of FIG. 2B will be described in particular. Other features may be the same as those of the a-a′ cross section of FIG. 2B.

The trench bottom region 65 is in contact with the lower end of at least one trench portion of a plurality of trench portions. The trench bottom region 65 of the present example is provided below the trench portions of the transistor portion 70 and the diode portion 80. The trench bottom region 65 may also be provided below the trench portion of the boundary region 90. The trench bottom region 65 is provided on an entire lower surface of the mesa portion, but may not be provided on a part of the lower surface of the mesa portion.

The trench bottom region 65 may be in contact with the drift region 18. In the present example, an upper end and a lower end of the trench bottom region 65 are in contact with the drift region 18. The semiconductor device 100 of the present example does not include the accumulation region 16, but may include the accumulation region 16. When the semiconductor device 100 includes the accumulation region 16, the upper end of the trench bottom region 65 may be in contact with a lower end of the accumulation region 16.

The trench bottom region 65 of the present example is of the second conductivity type. A doping concentration of the trench bottom region 65 may be lower than the doping concentration of the contact region 15. The doping concentration of the trench bottom region 65 may be lower than or the same as the doping concentration of the base region 14. When the trench bottom region 65 is of the second conductivity type, the doping concentration of the trench bottom region 65 may be 1.0E15 cm⁻³ or more and 2.0E17 cm⁻³ or less.

The semiconductor device 100 of the present example includes the trench bottom region 65, so that it is possible to reduce a feedback capacitance and reduce a turn-on loss Eon. In addition, in the semiconductor device 100 of the present example, even if the base region 14 and the anode region 19 are omitted, injected holes can be diffused to make hole distribution more uniform.

FIG. 8B is a view illustrating a modification of the XZ cross section including the a-a′ cross section in FIG. 2A. In the semiconductor device 100 of the present example, a region where the trench bottom region 65 is included is different from that of the a-a′ cross section of FIG. 8A. In the present example, differences from the a-a′ cross section of FIG. 8A will be described in particular. Other features may be the same as those of the a-a′ cross section of FIG. 8A.

The trench bottom region 65 is provided in the transistor portion 70 and is not provided in the diode portion 80. The trench bottom region 65 may be provided in both the main region 75 and the boundary region 90. The trench bottom region 65 may not be provided in the boundary region 90, or may be provided only in a part of the boundary region 90. The trench bottom region 65 may be provided to extend from the main region 75 to a middle of the boundary region 90 in the trench array direction. The trench bottom region 65 of the present example is provided to extend from the main region 75 to the boundary 78 between the transistor portion 70 and the diode portion 80 in the trench array direction.

In the semiconductor device 100 of the present example, when the trench bottom region 65 is not provided in the diode portion 80, the hole injection is suppressed to easily reduce the reverse recovery loss Err, compared with a case where the trench bottom region 65 is provided in the diode portion 80.

FIG. 8C is a view illustrating a modification of the XZ cross section including the a-a′ cross section in FIG. 2A. In the semiconductor device 100 of the present example, a conductivity type of the trench bottom region 65 is different from that of the a-a′ cross section of FIG. 8A. In the present example, differences from the a-a′ cross section of FIG. 8A will be described in particular. Other features may be the same as those of the a-a′ cross section of FIG. 8A.

The trench bottom region 65 is of the first conductivity type. The doping concentration of the trench bottom region 65 may be higher than the doping concentration of the drift region 18. When the semiconductor device 100 includes the accumulation region 16, the doping concentration of the trench bottom region 65 may be lower than the doping concentration of the accumulation region 16. When the trench bottom region 65 is of the first conductivity type, the doping concentration of the trench bottom region 65 may be 1.0E15 cm⁻³ or more and 1.0E16 cm⁻³ or less.

The trench bottom region 65 of the present example is provided in each of the main region 75, the diode portion 80, and the boundary region 90, but may be provided only in a partial region. The trench bottom region 65 of the present example is provided on the entire lower surface of the mesa portion, but may not be provided in a part of the lower surface of the mesa portion.

Note that the trench bottom region 65 may be appropriately applied to the semiconductor device 100 of another embodiment. In addition, the semiconductor device 100 of the present example includes the trench contact portion 58, but may have the structure in which the front-surface electrode portion 200 is connected to the semiconductor substrate 10 on the front surface 21, without being provided with the trench contact portion 58.

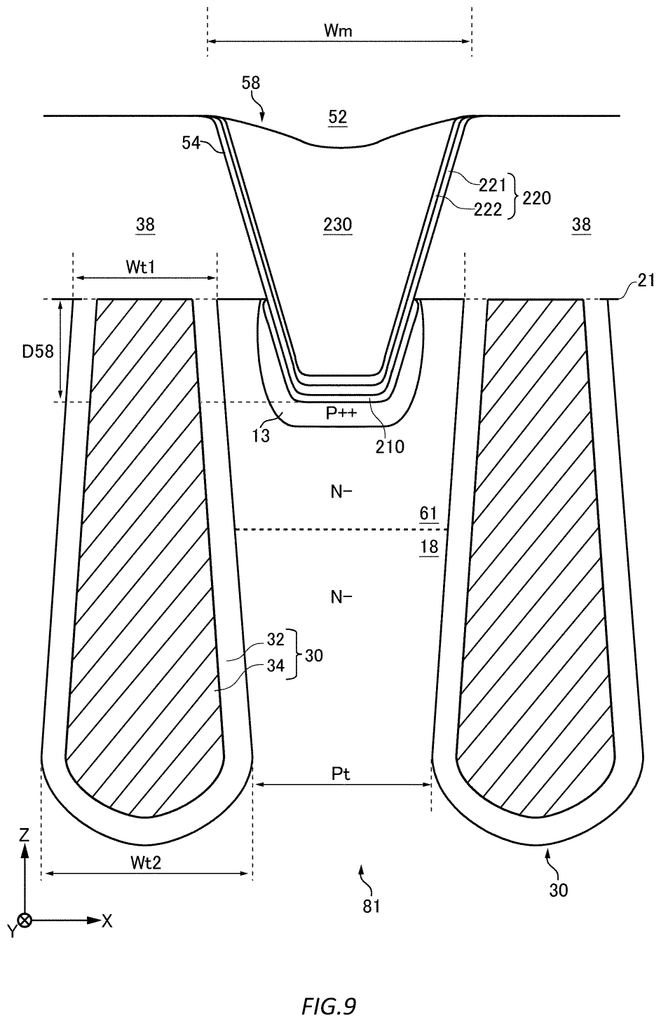

FIG. 9 is an enlarged view of a modification of the XZ cross section passing through the mesa portion 81. The mesa portion 81 of the present example is different from the mesa portion 81 of FIG. 2D in a shape of the trench portion. In the present example, differences from the mesa portion 81 in FIG. 2D will be described in particular, and other features may be the same as those of the mesa portion 81 in FIG. 2D. In the present example, the mesa portion 81 of the diode portion 80 will be described, but the shape of the trench portion may be applied to the mesa portion 71 of the transistor portion 70 and the mesa portion 91 of the boundary region 90.

This drawing illustrates the mesa portion 81 interposed between two adjacent dummy trench portions 30. The shape of the trench portion of the present example may be applied to the gate trench portion 40.

A plurality of trench portions may vary in the trench width Wt in the depth direction of the semiconductor substrate 10. The trench portion of the present example has the trench width Wt that gradually increases as a depth position of the semiconductor substrate 10 becomes deeper, but the shape of the trench portion is not limited thereto. The trench portion of the present example has a first trench width Wt1 and a second trench width Wt2.

The first trench width Wt1 is a trench width at a predetermined depth position of the semiconductor substrate 10. The first trench width Wt1 in the present example is a trench width at the front surface 21. The first trench width Wt1 may be 0.5 μm or more and 2.0 μm or less.

The second trench width Wt2 has a trench width larger than the first trench width Wt1 at a position deeper than a depth position of the first trench width Wt1. The second trench width Wt2 may be 1.1 times or more and 1.4 times or less the first trench width Wt1.

An interval Pt is an interval between two adjacent trench portions at a depth position where the trench portions are closest to each other. The interval Pt may be 0.1 μm or more and 0.5 μm or less. The interval Pt in the present example is an interval between the plurality of trench portions at the depth position of the second trench width Wt2.

In the semiconductor device 100 of the present example, by bringing the dummy trench portions 30 close to each other, a potential of a region where the dummy trench portions 30 are close to each other can be brought close to 0. With this configuration, the semiconductor device 100 of the present example can suppress the reach-through of the depletion layer to the front-surface electrode portion 200.

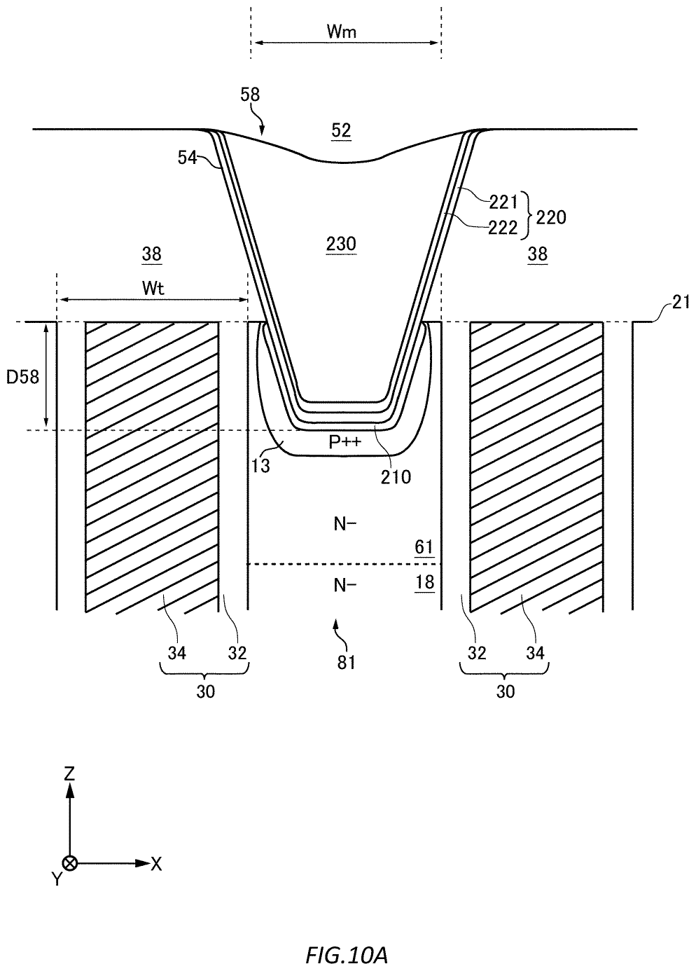

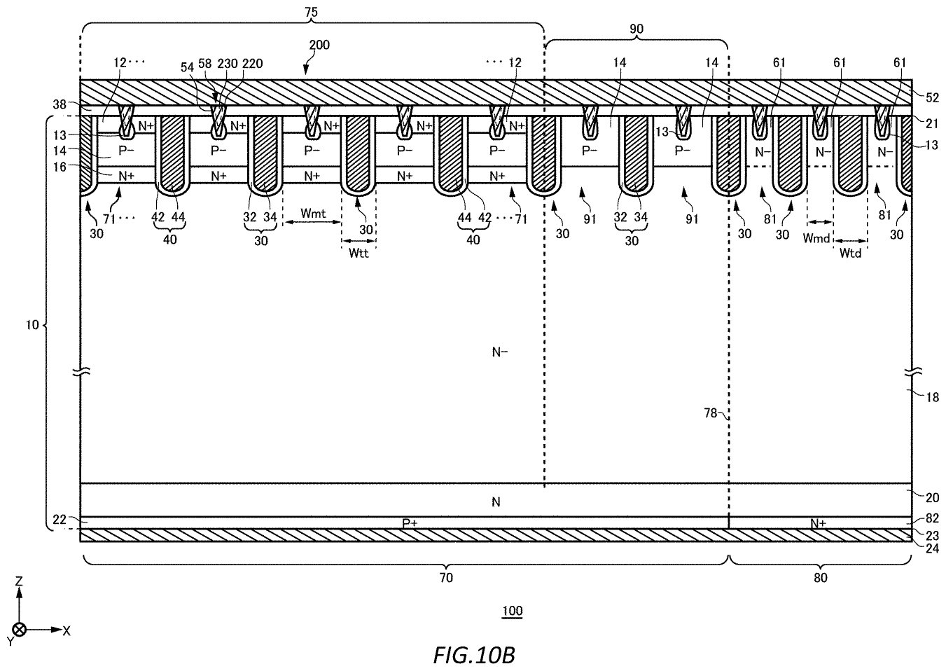

FIG. 10A is an enlarged view of a modification of the XZ cross section passing through the mesa portion 81. The mesa portion 81 of the present example is different from the mesa portion 81 of FIG. 2D in a ratio between the mesa width Wm and the trench width Wt. In the present example, differences from the mesa portion 81 in FIG. 2D will be described in particular, and other features may be the same as those of the mesa portion 81 in FIG. 2D. In the present example, the mesa portion 81 of the diode portion 80 will be described, but the present invention may be applied to the mesa portion 71 of the transistor portion 70 and the mesa portion 91 of the boundary region 90.

The mesa width Wm may be smaller than the trench width Wt. The mesa width Wm may be 0.2 μm or more and 0.5 μm or less. In the present example, the mesa width Wm of the mesa portion 81 is smaller than the trench width Wt of the dummy trench portion 30 adjacent to the mesa portion 81. The plug region 13 of the present example is separated from the dummy trench portion 30, but may be in contact with the dummy trench portion 30. The plug region 13 of the present example covers the side surface and the bottom surface of the trench contact portion 58, but may not cover a part of the side surface of the trench contact portion 58. The side surface of the trench contact portion 58 may be in contact with the first conductivity type mesa region 61.

The semiconductor device 100 of the present example has the mesa width Wm smaller than the trench width Wt. A structure of the present example may be appropriately applied to the semiconductor device 100 in another embodiment. By reducing the mesa width Wm, the depletion layer of the diode portion 80 can be pinched off to suppress a decrease in breakdown voltage.

FIG. 10B is a modification of the XZ cross section passing through the emitter region 12. In the semiconductor device 100 of the present example, the ratio between the mesa width Wm and the trench width Wt is different from that of the semiconductor device 100 of FIG. 2B. In the present example, differences from the semiconductor device 100 in FIG. 2B will be described in particular, and other features may be the same as those of the semiconductor device 100 in FIG. 2B.

A mesa width Wmd of the diode portion 80 is smaller than a mesa width Wmt of the transistor portion 70. A trench width Wtd of the diode portion 80 and a trench width Wtt of the transistor portion 70 are the same as each other, but may be different from each other. The trench width Wtd of the diode portion 80 may be larger than or smaller than the trench width Wtt of the transistor portion 70. Note that the mesa width Wmd of the diode portion 80 may be the same as the mesa width Wmt of the transistor portion 70. In this case, the trench width Wtd of the diode portion 80 may be larger than the trench width Wtt of the transistor portion 70.

In the semiconductor device 100 of the present example, the depletion layer in the diode portion 80 can be pinched off to suppress the decrease in breakdown voltage. In the transistor portion 70 of the present example, the mesa width Wmt is larger than the trench width Wtt, but the mesa width Wmt may be smaller than the trench width Wtt.

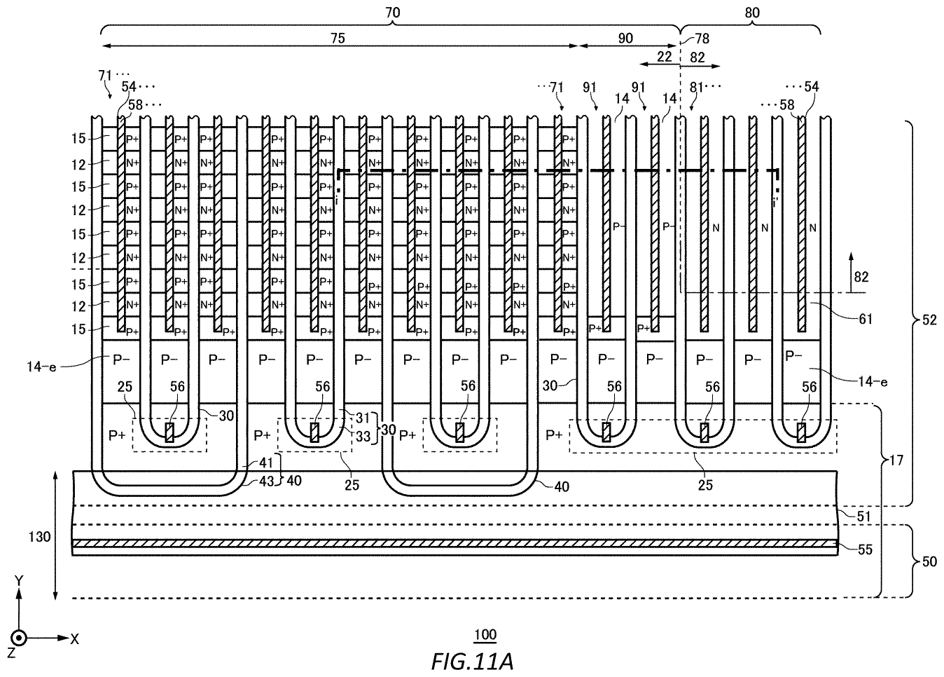

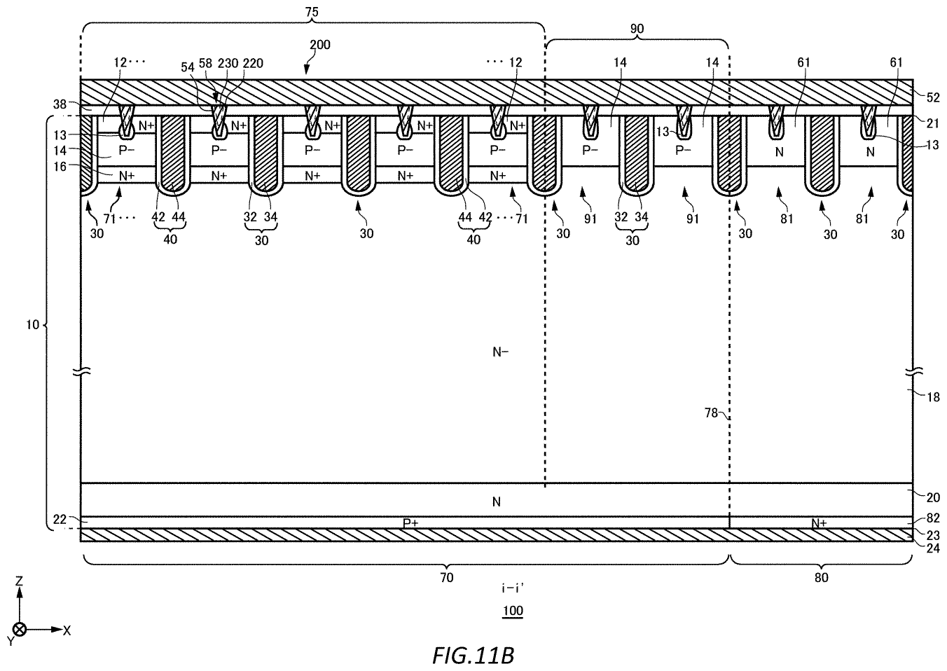

FIG. 11A is a top view of a modification of the semiconductor device 100. In the semiconductor device 100 of the present example, a magnitude of the doping concentration of the first conductivity type mesa region 61 is different from that of the first conductivity type mesa region 61 in FIG. 2A. In the present example, differences from the semiconductor device 100 in FIG. 2A will be described in particular. Other features may be the same as those of the semiconductor device 100 in FIG. 2A.

The doping concentration of the first conductivity type mesa region 61 is higher than the doping concentration of the drift region 18. The doping concentration of the first conductivity type mesa region 61 may be lower than the doping concentration of the accumulation region 16. The doping concentration of the first conductivity type mesa region 61 may be 1E15 cm⁻³ or more and 1E16 cm⁻³ or less.

FIG. 11B is a view illustrating an example of an XZ cross section including an i-i′ cross section in FIG. 11A. The XZ cross section, including the i-i′ cross section, is the XZ plane passing through the emitter region 12 in the main region 75. The cross-sectional structure of the mesa portion 91 may be the same as that of the mesa portion 91 on the XZ plane passing through the contact region 15 in the main region 75.

The mesa portion 91 includes the plug region 13 and the first conductivity type mesa region 61. The mesa portion 91 does not include the base region 14 below the contact hole 54. A lower surface of the first conductivity type mesa region 61 may be in contact with the drift region 18. An upper surface of the first conductivity type mesa region 61 may be exposed on the front surface 21 of the semiconductor substrate 10. The first conductivity type mesa region 61 may be in contact with the plug region 13. A depth position of the lower end of the first conductivity type mesa region 61 may be the same as or different from the depth position of the lower end of the base region 14.

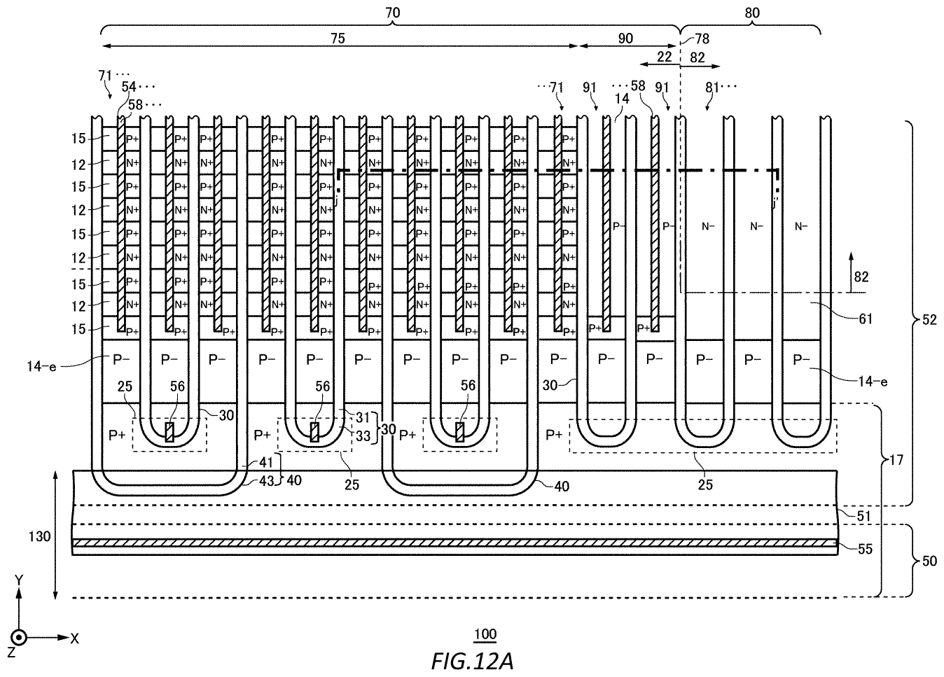

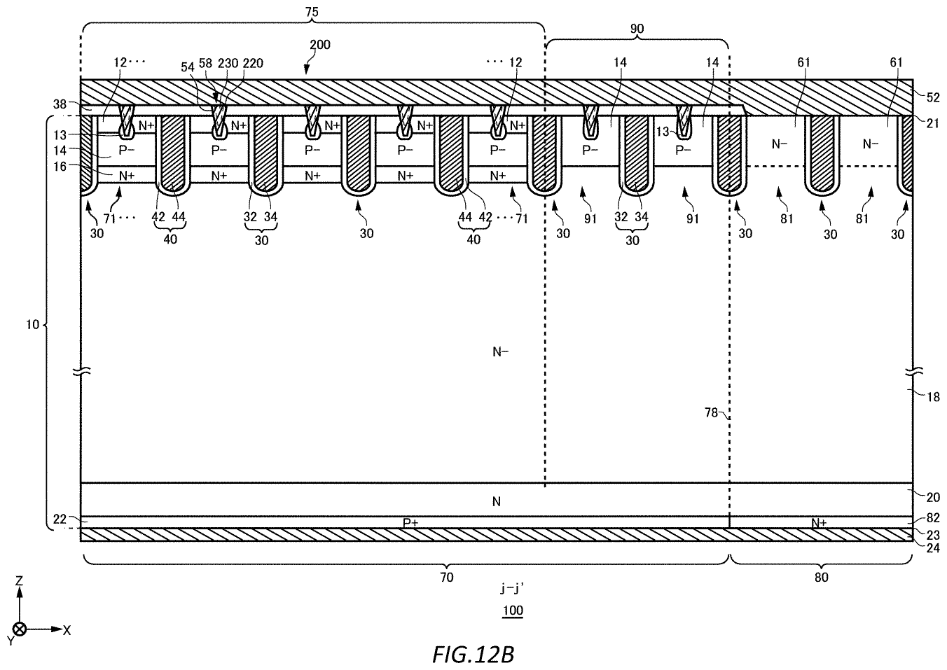

FIG. 12A is a top view of a modification of the semiconductor device 100. The semiconductor device 100 of the present example is different in the structure of the diode portion 80 from the diode portion 80 of FIG. 2A. In the present example, differences from the semiconductor device 100 in FIG. 2A will be described in particular. Other features may be the same as those of the semiconductor device 100 in FIG. 2A.

The diode portion 80 does not include the contact hole 54. The diode portion 80 of the present example does not include the trench contact portion 58. The diode portion 80 may not include the interlayer dielectric film 38 above the semiconductor substrate 10. In the diode portion 80, the front-surface electrode portion 200 is in direct contact with the front surface 21 of the semiconductor substrate 10. The first conductivity type mesa region 61 may be exposed on the front surface 21 of the semiconductor substrate 10 in the diode portion 80. The mesa portion 81 may include the base region 14-e and the well region 17 at its end portion in the trench extending direction.

The emitter electrode 52 of the present example may be in contact with the dummy conductive portion 34 of the dummy trench portion 30 as described later. With this configuration, a potential of the dummy conductive portion 34 becomes an emitter potential. The semiconductor device 100 of the present example includes the connection portion 25 at an end portion of the dummy trench portion 30 in the trench extending direction. The dummy trench portion 30 can be more reliably set to the emitter potential by being electrically connected to the emitter electrode 52 via the connection portion 25.

FIG. 12B is a view illustrating an example of an XZ cross section including a j-j′ cross section in FIG. 12A. The XZ cross section, including the j-j′ cross section, is the XZ plane passing through the emitter region 12 in the main region 75. The cross-sectional structure of the mesa portion 81 may be the same as that of the mesa portion 81 on the XZ plane passing through the contact region 15 in the main region 75.

The mesa portion 81 includes the first conductivity type mesa region 61. The first conductivity type mesa region 61 in the present example is the drift region 18. The mesa portion 81 may not include the base region 14 and the anode region 19. The mesa portion 81 is in contact with the emitter electrode 52 of the front-surface electrode portion 200. The mesa portion 81 does not include the plug region 13, but may include the plug region 13 on the front surface 21. The mesa portion 71 and the mesa portion 91 may be provided with the plug region 13.

In the diode portion 80, the front-surface electrode portion 200 covers upper sides of a plurality of trench portions and upper sides of a plurality of the mesa portions 81 between the plurality of trench portions, and is in contact with the plurality of trench portions and the plurality of mesa portions 81. That is, the interlayer dielectric film 38 may not be provided between the front-surface electrode portion 200 and the semiconductor substrate 10. The interlayer dielectric film 38 may not be provided above the dummy trench portion 30 and may not be provided above the mesa portion 81. By omitting the interlayer dielectric film 38, it is possible to avoid an electric field strength at an end portion of the interlayer dielectric film 38. The material of the front-surface electrode portion 200 may be Al—Si. The front-surface electrode portion 200 may form a Schottky junction with the first conductivity type mesa region 61.

The dummy trench portion 30 may be in contact with the front-surface electrode portion 200. The dummy conductive portion 34 of the present example is in contact with the emitter electrode 52. With this configuration, the potential of the dummy conductive portion 34 becomes the emitter potential. A recess formed by etching may be formed on an upper surface of the dummy trench portion 30.

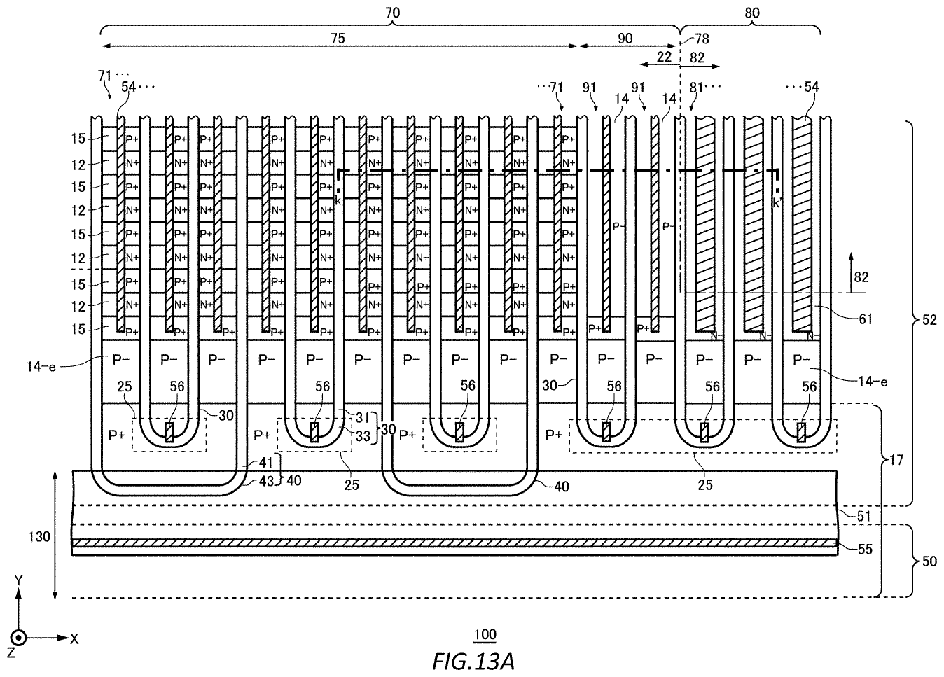

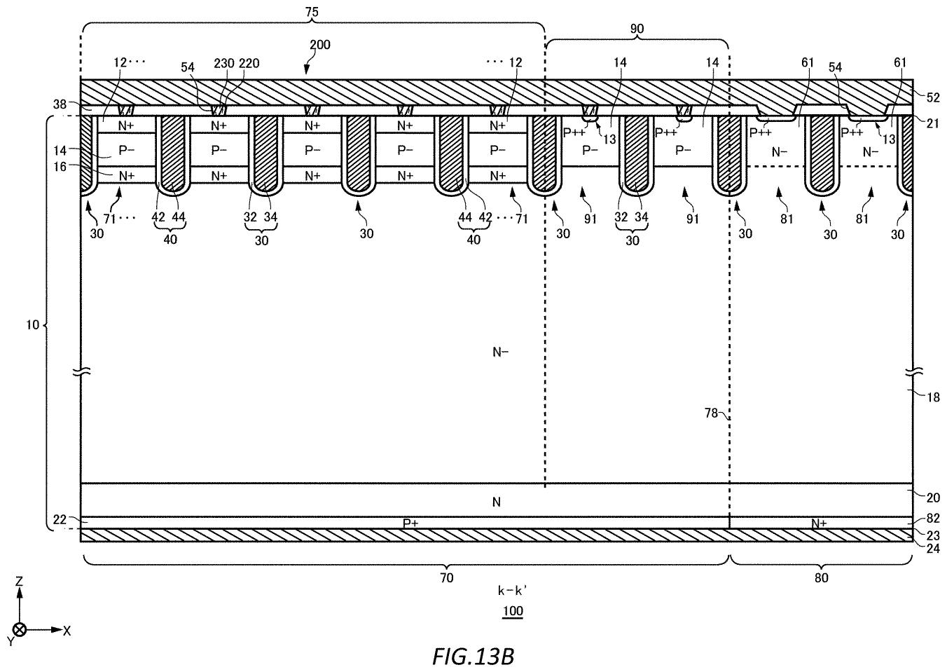

FIG. 13A is a top view of a modification of the semiconductor device 100. The semiconductor device 100 of the present example is different in the structure of the diode portion 80 from the diode portion 80 of FIG. 7A. In the present example, differences from the semiconductor device 100 in FIG. 7A will be described in particular. Other features may be the same as those of the semiconductor device 100 in FIG. 7A. The material of the emitter electrode 52 of the present example is Al—Si, but is not limited thereto. A width of the contact hole 54 of the mesa portion 81 is larger than a width of the contact hole 54 of the transistor portion 70, but the present invention is not limited thereto. The width of the contact hole 54 of the mesa portion 81 may be the same as the widths of the contact holes 54 of the mesa portion 71 and the mesa portion 91.

FIG. 13B is a view illustrating an example of an XZ cross section including a k-k′ cross section in FIG. 13A. The XZ cross section, including the k-k′ cross section, is the XZ plane passing through the emitter region 12 in the main region 75. The cross-sectional structure of the mesa portion 81 may be the same as that of the mesa portion 81 on the XZ plane passing through the contact region 15 in the main region 75. The front-surface electrode portion 200 is in contact with the semiconductor substrate 10 on the front surface 21.

The mesa portion 81 includes the plug region 13 and the first conductivity type mesa region 61. The plug region 13 is provided below the contact hole 54 and is in contact with the front-surface electrode portion 200. The plug region 13 is in contact with the first conductivity type mesa region 61. The first conductivity type mesa region 61 may not be in contact with the front-surface electrode portion 200. The first conductivity type mesa region 61 of the present example is the drift region 18, but is not limited thereto.

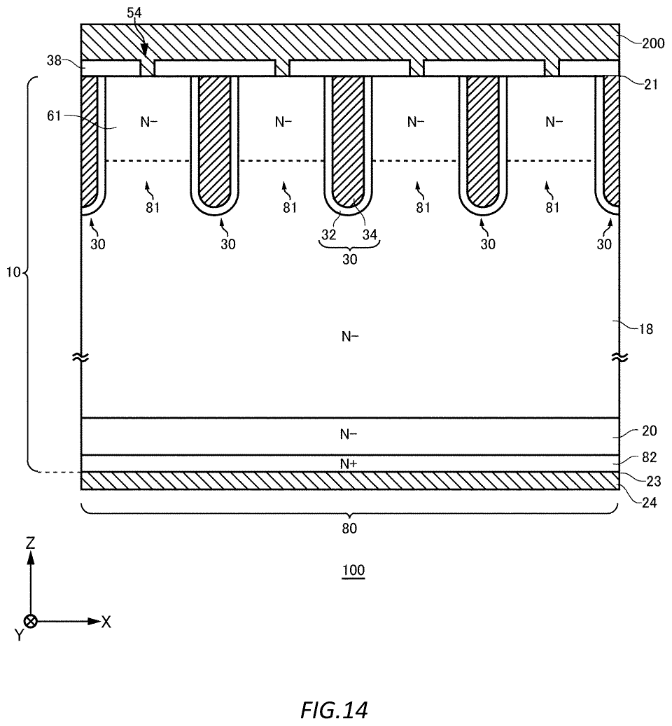

FIG. 14 is an example of a cross-sectional view of the semiconductor device 100. The semiconductor device 100 of the present example includes the diode portion 80, but does not include the transistor portion 70. The diode portion 80 of the present example includes a plurality of the dummy trench portions 30, but does not include the gate trench portion 40. The semiconductor device 100 of the present example includes the front-surface electrode portion 200 as a Schottky junction electrode. The dummy trench portion 30 may be set to an anode potential as a potential of the Schottky junction electrode.

The front-surface electrode portion 200 is formed of a material containing metal. At least a partial region of the front-surface electrode portion 200 may be formed of metal such as aluminum (Al) or a metal alloy such as an aluminum-silicon alloy (AlSi), an aluminum-silicon-copper alloy (AlSiCu), or an aluminum-copper alloy (AlCu). The front-surface electrode portion 200 may have barrier metal formed of titanium, a titanium compound, cobalt, a cobalt compound, nickel, a nickel compound, or the like under a region formed of aluminum or the like.

The semiconductor device 100 of the present example includes the contact hole 54 provided in the interlayer dielectric film 38. However, in the semiconductor device 100, the interlayer dielectric film 38 above the dummy trench portion 30 and the mesa portion 81 may be omitted. In this case, the front-surface electrode portion 200 may be in contact with an upper surface of the mesa portion 81 and the upper surface of the dummy trench portion 30.

Also in the semiconductor device 100 not including the transistor portion 70, the structure disclosed in other embodiments or the like may be appropriately applied. That is, the semiconductor device 100 of the present example may have the structure of the diode portion 80 described for the semiconductor device 100 including the transistor portion 70 and the diode portion 80.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A semiconductor device which includes a diode portion, comprising:
a drift region of a first conductivity type which is provided in a semiconductor substrate;
a plurality of trench portions which extend in a predetermined trench extending direction on a front surface side of the semiconductor substrate; and
a front-surface electrode portion which is provided above a front surface of the semiconductor substrate, wherein
the diode portion includes
a plug region of a second conductivity type which is provided in the semiconductor substrate and in contact with the front-surface electrode portion, and
a first conductivity type mesa region of the first conductivity type which is in contact with the plug region in a mesa portion between the plurality of trench portions.

2. The semiconductor device according to claim 1, wherein
the first conductivity type mesa region is the drift region.

3. The semiconductor device according to claim 1, wherein
the first conductivity type mesa region has a doping concentration higher than that of the drift region.

4. The semiconductor device according to claim 1, wherein
the front-surface electrode portion includes a trench contact portion which extends from the front surface of the semiconductor substrate in a depth direction of the semiconductor substrate, and
the plug region covers a side surface and a bottom surface of the trench contact portion at a depth position deeper than the front surface of the semiconductor substrate.

5. The semiconductor device according to claim 1, wherein
the front-surface electrode portion includes a trench contact portion which extends from the front surface of the semiconductor substrate in a depth direction of the semiconductor substrate,
the plug region covers a part of a side surface and a bottom surface of the trench contact portion at a depth position deeper than the front surface of the semiconductor substrate, and
the trench contact portion forms a Schottky junction with the first conductivity type mesa region on the side surface.

6. The semiconductor device according to claim 1, wherein
the plug region is in contact with an adjacent trench portion among the plurality of trench portions.

7. The semiconductor device according to claim 1, comprising
a trench bottom region which is in contact with a lower end of at least one trench portion of the plurality of trench portions, wherein
the trench bottom region is of the second conductivity type.

8. The semiconductor device according to claim 7, comprising
a transistor portion, wherein
the trench bottom region is provided in the transistor portion and is not provided in the diode portion.

9. The semiconductor device according to claim 7, wherein
the trench bottom region is of the first conductivity type.

10. The semiconductor device according to claim 1, wherein
a trench portion, which is provided in the diode portion, among the plurality of trench portions has
a first trench width at a predetermined depth position of the semiconductor substrate, and
a second trench width which has a trench width larger than the first trench width at a position deeper than a depth position of the first trench width.

11. The semiconductor device according to claim 1, wherein
a mesa width of the mesa portion between the plurality of trench portions is smaller than trench widths of the plurality of trench portions.

12. The semiconductor device according to claim 1, wherein
the front-surface electrode portion includes a silicide layer in contact with the plug region.

13. The semiconductor device according to claim 12, wherein
the front-surface electrode portion includes
a barrier metal portion which is in contact with the silicide layer, and
a plug portion which is provided inside the barrier metal portion in a contact hole.

14. The semiconductor device according to claim 1, comprising
a transistor portion, wherein
the transistor portion includes
a base region of the second conductivity type which is provided above the drift region,
an emitter region of the first conductivity type which is provided in the front surface of the semiconductor substrate and has a doping concentration higher than that of the drift region, and
a plurality of contact regions of the second conductivity type which are provided above the drift region and have a doping concentration higher than that of the base region.

15. The semiconductor device according to claim 14, wherein
a mesa width of the diode portion is smaller than a mesa width of the transistor portion.

16. The semiconductor device according to claim 14, wherein
the transistor portion includes a main region and a boundary region adjacent to the diode portion with respect to the main region, and
the boundary region does not include the base region in a region where a contact hole for connecting the semiconductor substrate to the front-surface electrode portion is provided.

17. The semiconductor device according to claim 14, wherein
the transistor portion includes a main region and a boundary region adjacent to the diode portion with respect to the main region, and
the boundary region includes
a first boundary mesa portion which does not include the base region in a region where a contact hole for connecting the semiconductor substrate to the front-surface electrode portion is provided, and
a second boundary mesa portion which is provided closer to the main region than the first boundary mesa portion and includes the base region in a region where a contact hole for connecting the semiconductor substrate to the front-surface electrode portion is provided.

18. The semiconductor device according to claim 14, comprising:
an interlayer dielectric film which is provided above the semiconductor substrate; and
a well region of the second conductivity type which is provided in the semiconductor substrate, wherein
the base region extends, in a trench extending direction, from an end portion of the well region toward an end portion of a contact hole provided in the interlayer dielectric film, and
a distance L0 between the base region and the end portion of the contact hole in the trench extending direction is greater than 0 μm and is within a width Wd of a depletion layer expanding from the base region toward the drift region.

19. A semiconductor device including a transistor portion and a diode portion, comprising:
a drift region of a first conductivity type which is provided in a semiconductor substrate;
a plurality of trench portions which extend in a predetermined trench extending direction on a front surface side of the semiconductor substrate; and
a front-surface electrode portion which is provided above a front surface of the semiconductor substrate, wherein
the transistor portion includes
a main region, and
a boundary region which is adjacent to the diode portion with respect to the main region,
the main region includes a base region of a second conductivity type which is provided above the drift region, and
the boundary region does not include the base region in a region where a contact hole for connecting the semiconductor substrate to the front-surface electrode portion is provided.

20. A semiconductor device which includes a diode portion, comprising:
a drift region of a first conductivity type which is provided in a semiconductor substrate;
a plurality of trench portions which extend in a predetermined trench extending direction on a front surface side of the semiconductor substrate; and
a front-surface electrode portion which is provided above a front surface of the semiconductor substrate, wherein
the diode portion includes a first conductivity type mesa region of a first conductivity type which is provided in a mesa portion between the plurality of trench portions, and
the front-surface electrode portion forms a Schottky junction with the first conductivity type mesa region.
